(19) United States
(12) Patent Application Publication
(10) Pub. No.: US 2026/0362938 A1
(43) Pub. Date: Nov. 12, 2026

(54) LIGHT EMITTING DISPLAY DEVICE

(71) Applicant: LG Display Co., Ltd., Seoul (KR)

(72) Inventors: Dong Cheol CHOE, Paju-si (KR); Su Min GWON, Paju-si (KR); Do Yeong SHIN, Paju-si (KR)

(73) Assignee: LG Display Co., Ltd., Seoul (KR)

(21) Appl. No.: 19/661,301

(22) Filed: Apr. 28, 2026

(30) Foreign Application Priority Data
Apr. 30, 2025 (KR) 10-2025-0057713

(51) Int. Cl. H10K 59/00; H10K 59/122; H10K 59/35; H10K 101/30

(52) U.S. Cl. CPC H10K 59/771; H10K 59/122; H10K 59/353; H10K 2101/30

(57) ABSTRACT

A light emitting display device can include a substrate having first to third sub-pixels, a first light emitting device, a second light emitting device, and a third light emitting device disposed on the first, second, and third light emitting devices emitting red, green, and blue light, respectively, in the first to third sub-pixels. The third light emitting device can include a first blue light emitting stack including a first blue light emitting layer between the anode and the charge generation layer, and a second blue light emitting stack including a second blue light emitting layer between the charge generation layer and the cathode, each of the first blue light emitting layer and the second blue light emitting layer includes a plurality of sub-light emitting layers, and a thickness of the second blue light emitting layer is greater than a thickness of the first blue light emitting layer.

### CROSS-REFERENCE TO RELATED APPLICATIONS

This application claims priority to Korean Patent Application No. 10-2025-0057713, filed in the Republic of Korea on Apr. 30, 2025, the entire contents of which is hereby expressly incorporated by reference as if fully set forth herein.

### BACKGROUND OF THE DISCLOSURE

### Field of the Disclosure

The present disclosure relates to a light emitting display device including a display device with improved efficiency and lifespan.

### Discussion of the Related Art

With the advent of the information society, displays for visually expressing electrical information signals have rapidly developed. In response to this, a variety of display devices with excellent performance such as slimness, low weight, and low power consumption are being developed.

Among the variety of display devices, a light emitting display device is increasingly competitive due to compactness and clear color when the light emitting display device does not require a separate light source due to light emitting display device being able to emit its own light.

The light emitting device can include an anode and a cathode facing each other as electrodes, and a light emitting layer is disposed between the anode and the cathode, whereby a common layer can be configured to transfer holes and electrons to the light emitting layer to generate light.

The light-emitting display devices can contain color light emitting layers to express a variety of colors but these light emitting layers can suffer differences in efficiency and lifespan characteristics. Thus, there is a need for development of light emitting devices that have color light emitting layers that address such different efficiency, lifespan characteristics, and structures.

Consequently, research is actively focused on improving durability of color emitting layers that may have relatively short lifespans so as to maintain uniform color in display devices over the lifetime of the light-emitting display devices.

### SUMMARY OF THE DISCLOSURE

Accordingly, the present disclosure is directed to a light emitting display device that substantially obviates one or more problems due to limitations and disadvantages of the related art.

An aspect of the present disclosure is to provide a light emitting device including a plurality of light emitting layers capable of improving efficiency, reducing operating voltage, and simultaneously extending the lifespan of at least some sub-pixels.

Another aspect of the present disclosure is to provide a light emitting display device that includes a plurality of light emitting layers each provided in first and second light emitting stacks overlapping each other, wherein the thickness relationship between the light emitting layers is defined such that the recombination region of holes and electrons is spaced from the interface between the light emitting layer and the common layer, thereby preventing a decrease in the lifespan caused by carrier or exciton accumulation at the interface of the light emitting layer.

Another aspect of the present disclosure is to provide a light emitting display device, in which a plurality of light emitting layers of each stack includes a plurality of sub-light emitting layers with different hosts, so that the triplet-triplet-annihilation TTA efficiency in the second sub-light emitting layer, which is the thickest layer, can be enhanced, and thus exciton utilization within the light emitting layer and light emitting efficiency can be improved.

Another aspect of the present disclosure is to provide a light emitting display device wherein, in a multi-light emitting layer, a first sub-light emitting layer adjacent to a hole transporting common layer includes a first host having a smaller HOMO energy level difference with a dopant, and a second sub-light emitting layer includes a second host having a HOMO energy level lower than that of the first host, so that hole transfer from the first sub-light emitting layer to the second sub-light emitting layer is facilitated and trapping of holes at an interface between the hole-transporting common layer and the light emitting layer is prevented.

Another aspect of the present disclosure is to provide a light emitting display device that includes a plurality of light emitting stacks in each sub-pixel in a top-emission manner to improve luminous efficiency and, in a structure having a plurality of stacked light emitting layers, to minimize or reduce color shift due to changes in viewing angle, thereby providing uniform visual perception regardless of variations in a viewing angle.

Another aspect of the present disclosure is to provide a light emitting display device that exhibits improved lifespan through a difference in dopant concentration included in light emitting layers of different stacks.

The aspect to be accomplished by the present disclosure is not limited to the above-mentioned aspect. Other aspects not mentioned herein will be clearly understood by those skilled in the art from the following description.

Additional advantages, aspects, and features of the disclosure will be set forth in part in the description which follows and in part will become apparent to those having ordinary skill in the art upon examination of the following or can be learned from practice of the disclosure. The aspects and other advantages of the disclosure can be realized and attained by the structure particularly pointed out in the written description and claims hereof as well as the appended drawings.

A light emitting display device according to an embodiment of the present disclosure includes a substrate including first to third sub-pixels, a transistor disposed in each of the first to third sub-pixels on the substrate, a planarization layer disposed on the transistor, a first light emitting device, a second light emitting device, and a third light emitting device disposed on the planarization layer, the first, second, and third light emitting devices emitting red, green, and blue light, respectively, in the first to third sub-pixels, and an encapsulation layer over the first to third light emitting devices.

Each of the first to third light emitting devices can include an anode and a cathode facing each other, and a charge generation layer between the anode and the cathode, and the third light emitting device can include a first blue light emitting stack having a first blue light emitting layer between the anode and the charge generation layer, and a second blue light emitting stack including a second blue light emitting layer between the charge generation layer and the cathode.

Each of the first blue light emitting layer and the second blue light emitting layer can include a plurality of sub-light emitting layers and a thickness of the second blue light emitting layer can be greater than a thickness of the first blue light emitting layer.

It is to be understood that both the foregoing general description and the following detailed description of the present disclosure are example and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a plan view illustrating a light emitting display device according to an embodiment of the present disclosure;

FIG. 2 is a cross-sectional view taken along line I-I′ of FIG. 1;

FIG. 3 is a cross-sectional view illustrating a light emitting device of first to third sub-pixels of FIG. 2;

FIG. 4 is an energy band diagram of first to third sub-light emitting layers of a blue light emitting layer included in a third sub-pixel of FIG. 3;

FIG. 5 is PL spectra of a blue dopant of the first and second blue light emitting layers, a green dopant of the first and second green light emitting layers, and a red dopant of the first and second red light emitting layers of FIG. 3;

FIG. 6 shows the location of the recombination region depending on the thickness of the first sub-light emitting layer of the multilayer blue light emitting layer structure in Experimental Examples 1 to 3;

FIG. 7 is an energy band diagram of a first blue light emitting layer and a second blue light emitting layer of a third sub-pixel in a light emitting display device according to an embodiment of the present disclosure;

FIG. 8 is an energy band diagram of a hole transport common layer and a blue light emitting layer in the first stack and the second stack;

FIG. 9 shows the location of recombination regions formed depending on the thickness of the first sub-light emitting layer in the first blue light emitting stack in Experimental Examples 4 to 6;

FIG. 10 shows the location of recombination regions formed depending on the thickness of the first sub-light emitting layer in the second blue light emitting stack in Experimental Examples 7 to 9;

FIG. 11 shows the viewing angle characteristics obtained by varying the thickness of the first sub-light emitting layer of the first blue light emitting layer when the cathode is formed of AgMg with a thickness of 15 nm and when the cathode is formed of IZO with a thickness of 20 nm;

FIG. 12 shows the viewing angle characteristics obtained by varying the thickness of the first sub-light emitting layer of the second blue light emitting layer when the cathode is formed of AgMg with a thickness of 15 nm and when the cathode is formed of IZO with a thickness of 20 nm;

FIG. 13 shows the viewing angle characteristics obtained by varying the thickness of the first sub-light emitting layer of the first blue light emitting layer when the cathode is formed of AgMg with a thickness of 15 nm and when the cathode is formed of ITO with a thickness of 20 nm;

FIG. 14 shows the viewing angle characteristics obtained by varying the thickness of the first sub-light emitting layer of the second blue light emitting layer when the cathode is formed of AgMg with a thickness of 15 nm and when the cathode is formed of ITO with a thickness of 20 nm; and

FIG. 15 is a cross-sectional view illustrating a light emitting display device according to another embodiment of the present disclosure.

### DETAILED DESCRIPTION OF THE EMBODIMENTS

Advantages and features of the present disclosure, and a method of achieving the advantages and features will become apparent with reference to the example embodiments of the present disclosure described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted. In addition, the names of elements used in the following description are selected in consideration of clarity of description of the disclosure, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present disclosure, where terms such as “including,” “having,” “comprising,” and the like are used, one or more components can be added, unless the term, such as “only,” is used. As used herein, the term “and/or” includes a single associated listed item and any and all of the combinations of two or more of the associated listed items. Further, the term “can” encompasses all the meanings and coverages of the term “may” and vice versa.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the disclosure, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “LUMO (lowest unoccupied molecular orbital) energy level” and “HOMO (highest occupied molecular orbital) energy level” of a layer refer to the LUMO energy level and HOMO energy level of a material that occupies most of a weight ratio of the layer, for example, a host material, unless the context clearly mentions that the LUMO energy level and the HOMO energy level mean the LUMO energy level and HOMO energy level of a dopant material with which the layer is doped, respectively.

Here, the HOMO energy level is obtained by measuring the voltage corresponding to a first peak at which electrons are discharged from a target material through cyclic voltammetry (CV) while comparing with a reference material whose HOMO energy level is known. For example, the HOMO energy level of a substance can be measured based on a substance whose oxidation potential and reduction potential are known.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer. The term “made of” for an element can fully encompass the meaning of being completely formed of the element, or simply including the element.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an out-coupling or emittance spectrum curve, which is determined by the structure and optical characteristics of an organic light-emitting element including the thicknesses of organic layers such as, for example, an electron transport layer.

Example embodiments of the present disclosure will be described in detail with reference to the accompanying drawings. In adding reference numerals to elements of each of the drawings, although the same elements are illustrated in other drawings, like reference numerals can refer to like elements.

Hereinafter, a light emitting display device according to an embodiment of the present disclosure will be described with reference to the accompanying drawings. All components of each light emitting display device according to all embodiments of the present disclosure are operatively coupled and configured.

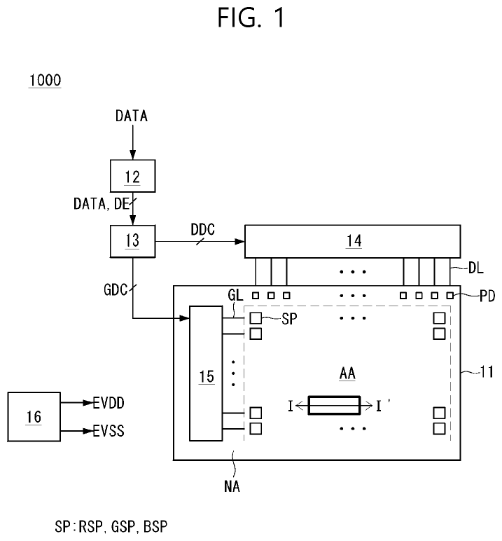

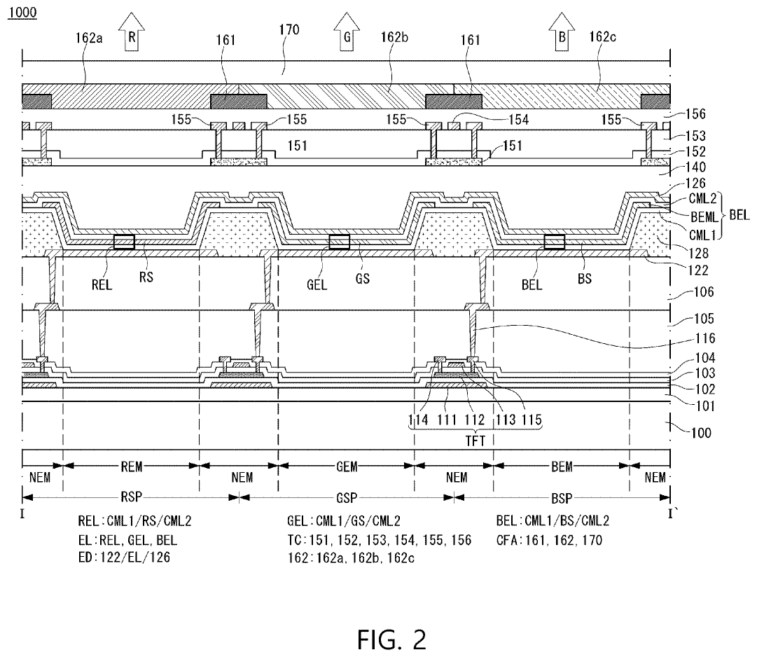

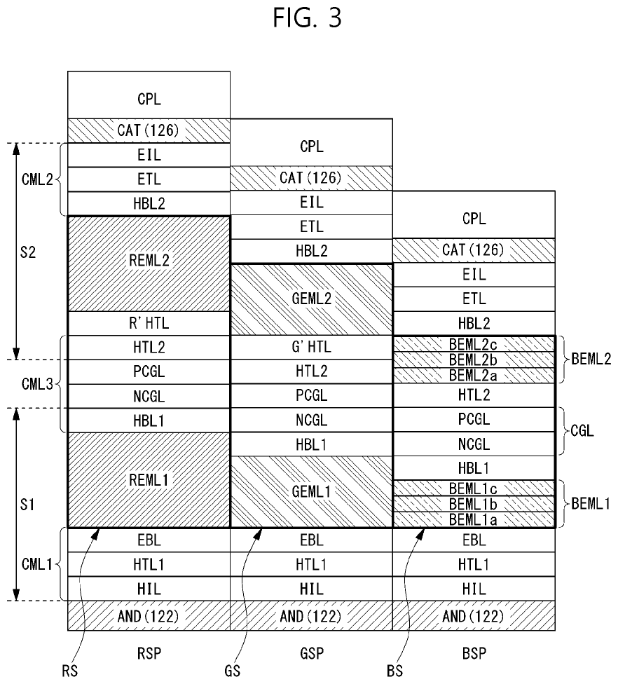

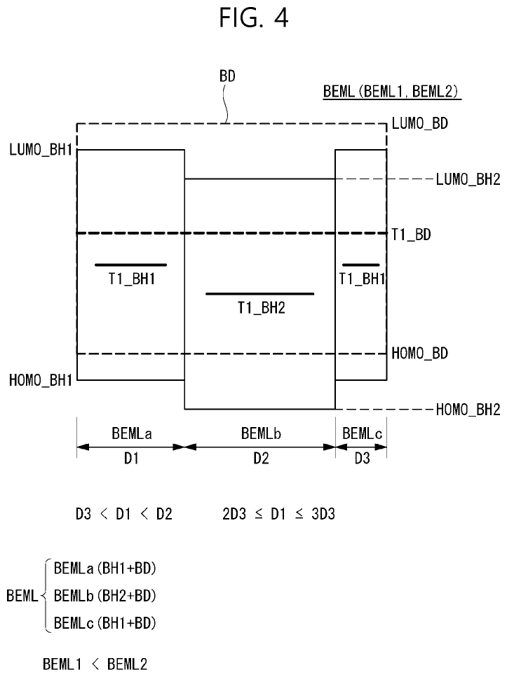

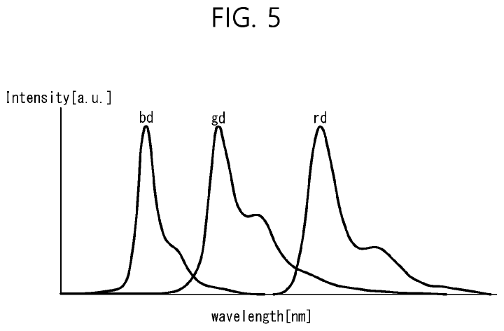

FIG. 1 is a schematic diagram illustrating a light emitting display device according to an embodiment of the present disclosure. FIG. 2 is a cross-sectional view taken along line I-I′ of FIG. 1. FIG. 3 is a cross-sectional view illustrating a light emitting device of first to third sub-pixels of FIG. 2. FIG. 4 is an energy band diagram of first to third sub-light emitting layers of a blue light emitting layer included in a third sub-pixel of FIG. 3. FIG. 5 is PL spectra of a blue dopant of the first and second blue light emitting layers, a green dopant of the first and second green light emitting layers, and a red dopant of the first and second red light emitting layers of FIG. 3.

As shown in FIG. 1, the light emitting display device 1000 according to an embodiment of the present disclosure includes a display panel 11, an image processor 12, a timing controller 13, a data driver 14, a scan driver 15, and a power supply 16.

The display panel 11 displays an image in response to a data signal DATA supplied from the data driver 14, a scan signal supplied from the scan driver 15, and power supplied from the power supply 16.

The display panel 11 can include sub-pixels SP disposed at each intersection of a plurality of gate lines GL and a plurality of data lines DL. The structure of the sub-pixel SP can vary depending on the type of the light emitting display device 1000.

One or more sub-pixels SP can constitute one unit pixel. For example, one unit pixel can include first to third sub-pixels RSP, GSP and BSP that emit red, green and blue light. Alternatively, one unit pixel can further include a sub-pixel that emits white light, in addition to the first to third sub-pixels. In an embodiment according to the present disclosure, the color type, arrangement type, arrangement order, or the like of the sub-pixels can be determined depending on the luminous characteristics, lifespan of the device, device disclosures, and the like, and are not limited thereto. For example, more than 4 sub-pixels can be used.

The display panel 11 can be divided into a display area (AA: inside a dotted area) where sub-pixels SP are disposed to display an image, and a non-display area NA around the display area AA. The scan driver 15 can be mounted in the non-display area NA of the display panel 11. In addition, the non-display area NA can include a pad portion PAD including a pad electrode PD.

Here, the display area AA is also called an “active area” and the non-display area NA is also called a “non-active area”.

The image processer 12 can output a data enable signal DE in addition to a data signal DATA supplied from the outside. The image processer 12 can output one or more of a vertical synchronization signal, a horizontal synchronization signal, and a clock signal in addition to the data enable signal DE, but these signals are omitted for convenience of description.

The timing controller 13 can receive a data signal DATA in addition to a driving signal from the image processer 12. The driving signal can include a data enable signal DE. In addition, the driving signal can include a vertical synchronization signal, a horizontal synchronization signal, and a clock signal. The timing controller 13 includes a data timing control signal DDC to control the operation timing of the data driver 14 and a gate timing control signal GDC to control the operation timing of the scan driver 15 based on the driving signal.

The data driver 14 samples and latches the data signal DATA supplied from the timing controller 13 in response to the data timing control signal DDC supplied from the timing controller 13, converts the resulting data signal DATA into a gamma reference voltage, and outputs the gamma reference voltage.

The data driver 14 can output the data signal DATA through the data lines DL. The data driver 14 can be provided as an integrated circuit IC. For example, the data driver 14 can be electrically connected to the pad electrode PD disposed in the non-display area NA of the display panel 11 through a flexible circuit film.

The scan driver 15 can output a scan signal in response to the gate timing control signal GDC supplied from the timing controller 13. The scan driver 15 can output a scan signal through the gate lines GL. The scan driver 15 can be implemented in the form of an integrated circuit IC or can be implemented in the form of a gate in panel GIP in the display panel 11.

The power supply 16 can output a high potential voltage and a low potential voltage for driving the display panel 11. The power supply 16 can supply a high potential voltage to the display panel 11 through a first power line EVDD (driving power line or pixel power line) and supply a low potential voltage to the display panel 11 through a second power line (EVSS) (auxiliary power line or a common power line).

The display panel 11 is divided into a display area AA and a non-display area NA, and includes a plurality of sub-pixels SP defined by gate lines GL and data lines DL which cross each other in the display area AA to form a matrix.

As shown in FIG. 2, each of the sub-pixels RSP, GSP, and BSP can include a light emitting portion REM, GEM or BEM that emits light and a non-light emitting portion NEM surrounding the light emitting portion.

As shown in FIG. 2, the light emitting display device 1000 according to an embodiment of the present disclosure can include a substrate 100 including first to third sub-pixels RSP, GSP, and BSP, a transistor TFT disposed on the substrate 100, a first planarization layer 105 and a second planarization layer 106 disposed on the transistor TFT, a light emitting device ED disposed on the second planarization layer 106, and an encapsulation layer 140 over the light emitting device ED, wherein the transistor TFT, the first planarization layer 105, the second planarization layer 106, the light emitting device ED, and the encapsulation layer 140 are sequentially provided in each of the first to third sub-pixels RSP, GSP, and BSP.

The light emitting display device 1000 can include a touch sensing unit TC capable of detecting a touch on the encapsulation layer 140 and a color filter array unit CFA disposed on each of the first to third sub-pixels RSP, GSP, and BSP to display a color.

The substrate 100 on which the first to third sub-pixels RSP, GSP, BSP are disposed can be formed of a single or multiple layers. For example, the first sub-pixel RSP can emit red light, the second sub-pixel GSP can emit green light, and the third sub-pixel BSP can emit blue light. The light emitting color emitted by the first to third sub-pixels RSP, GSP, BSP can be determined by a color light emitting layer included in the light emitting stack of the light emitting device ED disposed in each sub-pixel and a color filter included in the color filter array CFA. The sub-pixels shown in FIG. 1 include, for example, red, green, and blue sub-pixels, but sub-pixels emitting light of other colors, in addition to the red, green, and blue sub-pixels, can be further disposed on the substrate 100. However, embodiments of the present disclosure are not limited thereto, and other colors can be used.

The substrate 100 can include at least one of a glass substrate, a plastic film, and a metal plate having a predetermined supporting force. However, embodiments of the present disclosure are not limited thereto. The substrate 100 can be formed of a flexible material. For example, when the substrate 100 is formed of a plurality of layers, it can have a laminated structure of a first organic layer, an inorganic insulating layer, and a second organic layer. The outermost first organic layer can prevent the introduction of external impurities and have a protective function. The second organic layer can enable surface planarization of the formation surface of the internal array structure and can prevent charge transfer or impurity transfer from the outside to the inside. The inorganic insulating layer between the first and second organic layers can function to prevent moisture permeation and diffusion between the first and second organic layers and conductive impurities from moving to the second organic layer.

A multi-buffer layer 101 can be provided on the substrate 100. The multi-buffer layer 101 can function as a buffer layer and/or an active buffer layer. The multi-buffer layer 101 can function to prevent impurities from the wiring and the lower portion of the active layer 112 included in the internal array from being transferred upward, and can support and protect the upper structure. The multi-buffer layer 101 can include a plurality of inorganic insulating layers. For example, the inorganic insulating layers included in the multi-buffer layer 101 can include at least one of a silicon oxide layer, a silicon nitride layer, a silicon oxynitride layer, or an aluminum oxide layer. However, embodiments of the present disclosure are not limited thereto.

A thin film transistor TFT and a storage capacitor can be disposed in each sub-pixel RSP, GSP, BSP on the multi-buffer layer 101.

A light blocking layer 111 can be provided on the multi-buffer layer 101 to prevent light from being transmitted from below to the active layer 112 of the thin film transistor TFT.

A first insulating layer 102 can be disposed between the light blocking layer 111 and the active layer 112 for insulation. The first insulating layer 102 can be formed of an inorganic insulating material and can be formed of, for example, a silicon oxide (SiOx) layer, a silicon nitride (SiNx) layer, a silicon oxynitride (SiOxNy) layer, or a multi-layer thereof. However, embodiments of the present disclosure are not limited thereto.

A thin film transistor TFT can be disposed on each of a plurality of sub-pixels on the first insulating layer 102. For example, a thin film transistor TFT can include an active layer 112, a gate electrode 113 overlapping the active layer 112 with a second insulating layer 103 interposed therebetween, and a first source-drain electrode 114 and a second source-drain electrode 115 connected to both surfaces of the active layer 112.

For example, the storage capacitor can include a first storage electrode and a second storage electrode that overlap each other. At least one of the first and second storage electrodes can be formed of the same material as the active layer 112 and the other can include the same material as at least one of the gate electrode 113, the first and second source/drain electrodes 114, 115, or the light blocking layer 111. However, embodiments of the present disclosure are not limited thereto.

The second insulating layer 103 between the active layer 112 and the gate electrode 113 can function as a gate insulating layer.

The active layer 112 can include, for example, a silicon-based or oxide semiconductor. However, embodiments of the present disclosure are not limited thereto.

The silicon-based semiconductor can include crystalline and/or amorphous silicon. The oxide semiconductor can include at least one of gallium oxide, tin oxide, zinc oxide, indium oxide, iron oxide, or indium-gallium-zinc oxide. In some cases, the oxide semiconductor layer can be formed of a plurality of layers with different materials or composition ratios. At least one sub-pixel RSP, GSP, BSP can include a plurality of thin film transistors, and the thin film transistors can be disposed on different layers. For example, the sub-pixels RSP, GSP, BSP of the substrate 100 can include a plurality of thin film transistors having different active layers. For example, the first thin film transistor can be disposed closer to the substrate 100 as a silicon-based active layer and the second thin film transistor can be disposed higher than the first thin film transistor as an active layer, and can be provided in different layer structures. However, embodiments of the present disclosure are not limited thereto.

The active layer 112 can include a channel region overlapping the gate electrode 113 and source/drain regions connected to the first and second source/drain electrodes 114, and 115, respectively.

The second insulating layer 103 can be selectively disposed corresponding to the channel region of the active layer 112, or can be provided on the entire surface of the substrate 100 excluding the region through which the first and second source/drain electrodes 114, 115 pass. The second insulating layer 103 can function to insulate the active layer 112 and the gate electrode 113. The second insulating layer 103 can be formed of an inorganic insulating material, and can be formed of, for example, a silicon oxide (SiOx) layer, a silicon nitride (SiNx) layer, a silicon oxynitride (SiOxNy) layer, or a multi-layer thereof. However, embodiments of the present disclosure are not limited thereto.

The gate electrode 113 can be formed on the second insulating layer 103. The gate electrode 113 can be disposed to face the active layer 112 with a second insulating layer 103 interposed therebetween.

A third insulating layer 104 can be formed on the gate electrode 113 to cover and protect the gate electrode 113. Furthermore, the third insulating layer 104 can function to protect at least one electrode of a thin film transistor TFT, for example, the gate electrode 113, or the active layer 112. The third insulating layer 104 can be formed of an inorganic insulating material. For example, the third insulating layer 104 can be formed of a silicon oxide (SiOx) layer, a silicon nitride (SiNx) layer, a silicon oxynitride (SiOxNy) layer, or a multi-layer thereof. However, embodiments of the present disclosure are not limited thereto.

A first source-drain electrode 114 and a second source-drain electrode 115 can be disposed on the third insulating layer 104. The third insulating layer 104 and the second insulating layer 103 have contact holes to allow the first and second source/drain electrodes 114 and 115 to contact each other at both ends of the active layer 112, thereby removing the corresponding areas.

The gate electrode 113 and the first and second source/drain electrodes 114 and 115 can each have a single-layer or multilayer structure.

When the gate electrode 113 and the first and second source/drain electrodes 114 and 115 have a single-layer structure, they can be formed of one selected from the group consisting of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. In addition, when the gate electrode 113 and the first and second source/drain electrodes 114 and 115 have a multilayer structure, they can have a double-layer structure of molybdenum/aluminum-neodymium, molybdenum/aluminum, titanium/aluminum, molybdenum/titanium, or copper/molytitanium. Alternatively, the gate electrode 113 and the first and second source/drain electrodes 114 and 115 can have a triple-layer structure of molybdenum/aluminum-neodymium/molybdenum, molybdenum/aluminum/molybdenum, titanium/aluminum/titanium, or molybdenum/copper/molybdenum. However, embodiments of the present disclosure are not limited thereto.

However, the present disclosure is not limited thereto, and the gate electrode 113 and the first and second source electrodes 114 and 115 can also have a multi-layer structure formed of any one material selected from the group consisting of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto.

A first planarization layer 105 and a second planarization layer 106 can be sequentially formed on the third insulating layer 104. The first and second planarization layers 105 and 106 planarize the lower structure and prevent steps at the portion where the light emitting device ED is formed, thereby securing a light emitting area and stabilizing the characteristics of the surface where the light emitting device is formed.

The first planarization layer 105 can be provided with a contact hole and the contact hole can be provided with a connection electrode 116 connected to the second source/drain electrode 115. The connection electrode 116 can be disposed on the same layer as at least one of a first power line configured to be connected to the transistors of the sub-pixels RSP, GSP, and BSP, the storage capacitor, and some of the light emitting devices and to supply a high-potential voltage (EVDD), a second power line configured to supply a low-potential voltage (EVSS), a reference voltage line, or a reset voltage line.

The second planarization layer 106 can be disposed to cover the connection electrode 116 and the first planarization layer 105.

The first and second planarization layers 105 and 106 can each include an organic material. The organic material can include at least one material selected from the group consisting of an acrylic resin, a phenolic resin, a polyimide resin, an unsaturated polyester resin, a polyamide resin, benzocyclobutene, a polyphenylene resin, and a polyphenylene sulfide resin. However, embodiments of the present disclosure are not limited thereto, and other materials can be used.

For example, the connection electrode 116 can be formed as a multilayer including one selected from the group consisting of molybdenum (Mo), aluminum (Al), chromium (Cr), gold (Au), titanium (Ti), nickel (Ni), neodymium (Nd), and copper (Cu) or an alloy thereof. However, the embodiments of the present disclosure are not limited thereto. In some cases, the connection electrode 116 can be omitted. When the connection electrode 116 is omitted, one of the first and second source-drain electrodes 114 and 115 can be directly connected to the anode (122, AND) of the light emitting device ED.

The light emitting device ED includes a stack of an anode (122, AND), an intermediate layer (EL: REL, GEL, BEL), and a cathode 126. The intermediate layers (EL: REL, GEL, BEL) can include two or more light emitting stacks in each sub-pixel RSP, GSP, and BSP. The sub-pixels RSP, GSP, and BSP can include color light emitting layers REML1/REML2, GEML1/GEML2, and BEML1/BEML2 that emit light of different colors and are vertically spaced apart from each other with a charge generation layer CGL therebetween. The pattern configurations for each sub-pixel RSP, GSP, or BSP in the intermediate layer EL are referred to as a “red light emitting pattern portion RS”, a “green light emitting pattern portion GS”, and a “blue light emitting pattern portion BS”.

The specific configuration of the light emitting device ED will be described later with reference to FIG. 2, etc., and the upper configuration of the light emitting device ED will be described first.

The edge of the anode 122 of each sub-pixel RSP, GSP, BSP can overlap the bank 128. The area of the anode 122 exposed from the bank 128 can be a light emitting portion REM, GEM or BEM. The bank 128 opens the light emitting portion REM, GEM or BEM of each sub-pixel RSP, GSP or BSP. The bank 128 can include an organic or inorganic insulating material. The bank 128 can include a transparent insulating material and an opaque insulating material. In another embodiment of the present disclosure, the bank 128 can have a configuration in which an opaque insulating material and a transparent insulating material are laminated.

The multiple layers included in the intermediate layer (EL: REL, GEL, BEL), or at least the first common layer CML1 and CML2, can be provided in common across the entire display area AA.

The cathode 126 can be a common layer that is commonly disposed across the sub-pixels SP and applies the same voltage. For this purpose, the cathode 126 can extend from the display area AA to a portion of the non-display area (NA).

The cathode 126 can be a light-transmitting electrode. The cathode 126 can include a transparent conductive material TCO, such as indium tin oxide (ITO) or indium zinc oxide (IZO), which transmits light, or a semi-transmissive conductive material, such as magnesium (Mg), silver (Ag), or an alloy of magnesium (Mg) and silver (Ag). When the cathode 126 includes a semi-transparent metal material, the luminous efficiency can be increased by the microcavity. When the cathode 126 includes a semi-transparent metal material, the thickness thereof can be thin enough to allow light to pass therethrough.

The anode 122 includes a reflective electrode to prevent light generated in the intermediate layer EL from being transmitted to the light shielding components beneath the anode 122. Light generated in the intermediate layer EL can resonate between the cathode 126 and the anode 122, and be ultimately emitted upward through the cathode 126. Because the anode 122 includes a reflective component, although it overlaps wirings and a transistor TFT, the light emitted from the light emitting device ED can be recognized in the light emitting portion REM, GEM or BEM without interference from the components beneath the light emitting device ED, without affecting the disposition.

The light emitting display device according to the embodiments of the present disclosure exhibits a top emission method in which the emission direction is upward. In this case, the anode 122 includes a reflective electrode and the light generated from the intermediate layer EL is reflected and re-reflected between the anode 122 and the cathode 126, resonates, and is finally emitted toward the cathode 126. The sub-pixels RSP, GSP, and BSP can have different microcavity characteristics corresponding to each color by varying the thicknesses of the red emission pattern portion RS, the green emission pattern portion GS, and the blue light emitting pattern portion BS, and the first and second optical compensation layers R′HTL and G′HTL.

As shown in FIG. 3, a capping layer CPL is further included on the cathode 126 to enhance the light output effect from the light emitting device ED through the refraction phenomenon and to protect the upper surface of the light emitting device. The capping layer CPL can include a plurality of insulating material layers with different refractive indices. In terms of optical function, the entire structure from the anode AND to the capping layer CPL can be considered to constitute the light emitting device ED. The capping layer CPL is disposed between the cathode CAT and the encapsulation layer 140.

An encapsulation layer 140 protecting the light emitting device ED can be further provided. The encapsulation layer 140 can have a single-layer structure or a multilayer structure. When the encapsulation layer 140 is composed of multiple layers, it can be formed by laminating at least one inorganic encapsulating layer and at least one organic encapsulating layer. The inorganic encapsulating layer prevents moisture penetration and the organic encapsulating layer can cover particles and planarize the surface. On a flat surface, the organic encapsulation layer can be disposed inside the inorganic encapsulation layer. In this case, the phenomenon of moisture permeation through the organic encapsulation layer when exposed can be prevented.

The touch sensing unit TC can be included on the encapsulation layer 140. The touch sensing unit TC can be directly disposed on the encapsulation layer 140. The touch sensing unit TC can include a bridge electrode 151, first and second touch insulating layers 152 and 153 disposed on the bridge electrode 151, a first touch electrode 154 and a second touch electrode 155 disposed in different directions on the second touch insulating layer 153, and a touch protection layer 156 configured to cover the first and second touch electrodes 154 and 155 and to protect the lower configuration. Either of the first touch electrode 154 and the second touch electrode 155 can be connected to the bridge electrode 151. The illustrated example shows a configuration in which the second touch electrode 155 passes through the second and first touch insulating layers 153 and 152 and is connected to the bridge electrode 151. However, the present disclosure is not limited thereto and the first touch electrode 154 can also be connected to the bridge electrode.

At least one of the bridge electrode 151 or the first and second touch electrodes 154 and 155 can include a mesh structure.

Furthermore, the bridge electrode 151 and the first and second touch electrodes 154 and 155 can be disposed to overlap the bank 128 to prevent external visibility.

The bridge electrode 151 and the first and second touch electrodes 154 and 155 can each be independently formed of a transparent electrode such as ITO or IZO, or one selected from the group consisting of molybdenum (Mo), aluminum (Al), chromium (Cr), gold (Au), titanium (Ti), nickel (Ni), neodymium (Nd), and copper (Cu), or an alloy thereof, or a multi-metal laminate structure. However, embodiments of the present disclosure are not limited thereto.

A color filter array CFA including a light shielding layer 161 and color filters (162: 162a, 162b, 162c) can be disposed on the touch protection layer 156 at the top of the touch sensing unit TC. The color filter array CFA can further include a transparent protective layer 170 that protects the light shielding layer 161 and the color filter 162. The light shielding layer 161 can block light in the entire visible light wavelength range. The color filter 162 can include a red color filter 162a disposed in the first sub-pixel RSP, a green color filter 162b disposed in the second sub-pixel GSP, and a blue color filter 162c disposed in the third sub-pixel BSP. The red color filter 162a has selective transmittance for red wavelengths and has light shielding properties for visible light other than the red wavelength. Similarly, the green color filter 162b has light shielding properties for visible light other than the green wavelength. The blue color filter 162c has light shielding properties for visible light other than the blue wavelength.

Accordingly, red light generated through the intermediate layer REL emitting red light in the first sub-pixel RSP can pass through the red color filter 162a without loss in the red wavelength band and be emitted to the outside, and similarly, green light generated through the intermediate layer GEL emitting green light in the second sub-pixel GSP can pass through the green color filter 162b without loss in the green wavelength band and be emitted to the outside, and blue light generated through the intermediate layer BEL emitting blue light in the third sub-pixel BSP can pass through the blue color filter 162c without loss in the blue wavelength band and be emitted to the outside.

From the perspective of external light reflection, the configuration of the color filter array CFA functions as an anti-reflection layer by shielding external light. For example, the light shielding layer 161 disposed in the non-light emitting portion NEM can block external light from being transmitted downward. The red color filter 162a, the green color filter 162b, and the blue color filter 162c, disposed corresponding to the light emitting portions REM, GEM, BEM, respectively, can block light outside of the wavelengths that have selective transmittance, thereby preventing external light reflection from each light emitting portion REM, GEM, BEM.

The anode (122, AND) is independently disposed in each sub-pixel RSP, GSP, BSP. The anode (122, AND) is also referred to as a “first electrode” or “pixel electrode” which is connected to a thin film transistor and enables selective operation of the light emitting device disposed in each sub-pixel. The cathode 126 is also referred to as a “second electrode” or “common electrode” because it is commonly provided in a plurality of sub-pixels RSP, GSP, BSP disposed on the substrate 100. The cathode (126, CAT) can be grounded or connected to a low-voltage line.

The anodes (122, AND) of adjacent sub-pixels RSP, GSP, BSP are spaced apart from each other to enable independent signal application. The anodes (122, AND) can be connected to the connection electrode 116 through contact holes provided in the second planarization layer 106 or directly connected to the thin film transistor TFT through contact holes continuously provided in the first and second planarization layers 105 and 106.

The anode 122 can include a metal material having high reflectivity. For example, the anode 122 can be formed as a multilayer structure such as a laminated structure of aluminum (Al) and titanium (Ti) (Ti/Al/Ti), a laminated structure of aluminum (Al) and indium tin oxide (ITO) (ITO/Al/ITO), an APC (Ag/Pd/Cu) alloy, a laminated structure of an APC alloy and ITO (ITO/APC/ITO), a laminated structure of silver (Ag) and molybdenum/titanium alloy (Ag/MoTi), or can include a single layer structure formed of one material selected from silver (Ag), aluminum (Al), molybdenum (Mo), gold (Au), magnesium (Mg), calcium (Ca), barium (Ba), or an alloy of two or more materials. However, embodiments of the present disclosure are not limited thereto. The anode 122 can be referred to as a “reflective electrode”.

An intermediate layer EL is provided on the anode 122. The intermediate layer EL can include a first hole-related common layer CML1, an organic light emitting layer (EML), and a second electron-related common layer CML2.

Referring to FIG. 2, the first common layer CML1 is a hole-related common layer and can include a hole injection layer HIL, a first hole transport layer HTL1, and an electron blocking layer EBL.

The second common layer CML2 is an electron-related common layer, and can include a second hole blocking layer HBL2, an electron transport layer ETL, and an electron injection layer EIL.

A cathode CAT 126 can be disposed on the second common layer CML2. The cathode 126 can be a reflective-transmitting electrode or a light-transmitting electrode. When the cathode 126 is a light-transmitting electrode, it can be a transparent conductive material TCO, such as ITO (indium tin oxide) or IZO (indium zinc oxide), which transmits light. When the cathode 126 is a reflective-transmitting electrode, it can include a semi-transmissive conductive material, such as magnesium (Mg), silver (Ag), or an alloy of magnesium (Mg) and silver (Ag). When the cathode 126 includes a semi-transmissive conductive material, the luminous efficiency can be increased by a micro cavity. When the cathode 126 includes a semi-transmissive metal material, the thickness thereof can be thin enough to allow light to pass through.

The first common layer CML1, the second common layer CML2, and the cathode (126, CAT) are provided in common in the first to third sub-pixels RSP, GSP, BSP, and are disposed not only in the light emitting portions REM, GEM, BEM of the first to third sub-pixels RSP, GSP, BSP but also in the non-light emitting portions NEM, as shown in FIG. 1.

The first common layer CML1 and the second common layer CML2 are provided in common in the display area AA including a plurality of sub-pixels on the substrate 100 and can be disposed continuously and without interruption.

In the light emitting display device according to the embodiment of the present disclosure, the light emitting devices EDs provided in the first to third sub-pixels RSP, GSP, BSP each include two or more stacks, each distinguished by a charge generation layer. In the first to third sub-pixels RSP, GSP, BSP, the light emitting device includes a light emitting pattern portion RS, GS, and BS, including color light emitting layers respectively corresponding to the first to third sub-pixels RSP, GSP, and BSP, which are separately patterned and disposed between at least the first common layer CML1 and the second common layer CML2.

FIG. 2 illustrates an example in which the intermediate layers REL, GEL, and BEL of the light emitting devices of the first to third sub-pixels RSP, GSP, BSP each include two stacks.

The first sub-pixel RSP includes a first common layer CML1, a red light emitting pattern portion RS, and a second common layer CML2, wherein the red light emitting pattern portion RS includes a first red light emitting layer REML1 and a second red light emitting layer REML2 included in different light emitting stacks S1 and S2 with a charge generation layer CGL interposed therebetween. The red light emitting pattern portion RS can further include a first hole blocking layer HBL1, a charge generation layer CGL, a second hole-transport layer HTL2, and a first optical compensation layer R′HTL between the first red light emitting layer REML1 and the second red light emitting layer REML2.

The first and second red light emitting layers REML1 and REML2 and the first optical compensation layer R′HTL in the first sub-pixel RSP are spaced apart from the second and third sub-pixels GSP and BSP and thus have a patterned configuration. On the other hand, the first hole blocking layer HBL1, the charge generation layer CGL, and the second hole transport layer HTL2 of the red light emitting pattern RS can be formed as a third common layer CML3 that extends horizontally continuously in the sub-pixels RSP, GSP, BSP. The charge generation layer CGL can include, for example, an n-type charge generation layer NCGL that generates electrons and supplies the electrons to the first light emitting stack S1, and a p-type charge generation layer PCGL that generates holes and supplies the holes to the second light emitting stack S2. However, embodiments of the present disclosure are not limited thereto.

The second sub-pixel GSP includes a first common layer CML1, a green light emitting pattern portion GS, and a second common layer CML2, wherein the green light emitting pattern portion GS includes a first green light emitting layer GEML1 and a second green light emitting layer GEML2 included in different light emitting stacks S1 and S2 with a charge generation layer CGL therebetween. The green light emitting pattern portion GS can further include a third common layer CML3, in which a first hole blocking layer HBL1, a charge generation layer CGL, and a second hole transport layer HTL2 are stacked, and a second optical compensation layer G′HTL between the first green light emitting layer GEML1 and the second green light emitting layer GEML2.

The third sub-pixel BSP includes a first common layer CML1, a blue light emitting pattern portion BS, and a second common layer CML2. The blue light emitting pattern portion BS includes a first blue light emitting layer BEML1 and a second blue light emitting layer BEML2 included in different light emitting stacks S1 and S2 with a charge generation layer CGL therebetween. The blue light emitting pattern portion BS can further include a third common layer CML3, in which a first hole blocking layer HBL1, a charge generation layer CGL, and a second hole transport layer HTL2 are stacked, between the first blue light emitting layer BEML1 and the second blue light emitting layer BEML2.

In the light emitting display device according to one embodiment of the present disclosure, the first blue light emitting layer BEML1 can include first to third sub-light emitting layers BEML1a, BEML1b, and BEML1c, each having a different host, and the second blue light emitting layer BEML2 can include first to third sub-light emitting layers BEML2a, BEML2b, and BEML2c, each having a different host. The first sub-light emitting layer BEML1a and BEML2a, the second sub-light emitting layer BEML1b and BEML2b, and the third sub-light emitting layer BEML1c and BEML2c are disposed in that order. The second sub-light emitting layer BEML1b and BEML2b is an intermediate layer in each blue light emitting layer BEML1 and BEML2, the first sub-light emitting layer BEML1a and BEML2a is relatively close to the anode (AND, 122), and the third sub-light emitting layer BEML1c and BEML2c is relatively close to the cathode (CAT, 126).

As shown in FIG. 3, in at least one blue light emitting layer BEML among the first blue light emitting layer BEML1 and the second blue light emitting layer BEML2, the first sub-light emitting layer BEMLa and the third sub-light emitting layer BEMLc can include the same first host BH1 and the same blue dopant BD. The second sub-light emitting layer BEMLb disposed between the first sub-light emitting layer BEMLa and the third sub-light emitting layer BEMLc includes a second host BH2 having a triplet energy level T1_BH2 lower than the triplet energy level T1_BH1 of the first host BH1 and a blue dopant BD. When the blue light emitting layer BEML includes consecutive first to third sub-light emitting layers BEMLa, BEMLb, and BEMLc, the blue dopant BD can include the same material.

There is a difference in the host between adjacent sub-light emitting layers BEMLa, BEMLb, and BEMLc. Dexter energy transfer can occur from the first and third sub-light emitting layers BEMLa and BEMLc, which include the first host BH1, which has a high triplet energy level, to the second sub-light emitting layer BEMLb, which has a low triplet energy level through an interface between the first sub-light emitting layer BEMLa and the second sub-light emitting layer BEMLb, and the interface between the third sub-light emitting layer BEMLc and the second sub-light emitting layer BEMLb.

The first host BH1 can be, for example, a compound including a pyrene derivative. The second host BH2 can be, for example, a compound including an anthracene derivative. However, embodiments of the present disclosure are not limited thereto.

The blue dopant BD is a fluorescent dopant having an emission peak at a wavelength of 420 nm to 495 nm. The blue dopant BD can be, for example, a boron-based fluorescent dopant containing boron in the core. However, embodiments of the present disclosure are not limited thereto. The triplet energy level T1_BD of the blue dopant BD can be higher than the triplet energy levels T1_BH1 and T1_BH2 of the first and second hosts BH1 and BH2, respectively. For example, a triplet energy level T1_BD1 of the first blue dopant BD1 can be higher than the triplet energy levels T1_BH1 and T1_BH2 of the first and second hosts BH1 and BH2, respectively.

The blue dopant BD commonly provided in the first to third sub-light emitting layers BEMLa, BEMLb, and BEMLc has a hole trapping property and is transferred to the blue light emitting layer BEML through the electron blocking layer EBL or the second hole transport layer HTL2, and electrons are transferred through the first or second hole blocking layer HBL1 and HBL2, a recombination region is mainly formed at a position in the first sub-light emitting layer BEMLa adjacent to the electron blocking layer EBL or the second hole transport layer HTL2 that directly transfers holes to the blue light emitting layer BEML. In the recombination region, singlet excitons are generated by the combination of holes and electrons, and the singlet excitons fall to the ground state, leading to immediate light emission. Accordingly, the first sub-light emitting layer BEMLa has high immediate luminescence efficiency, but in the luminescent display devices of the embodiments of the present disclosure, the second sub-light emitting layer BEMLb contains a second host BH2 having a relatively low triplet energy level, and receives energy through the first and third sub-light emitting layers BEMLa and BEMLc, thereby generating abundant triplet excitons in the second sub-light emitting layer BEMLb, and delayed fluorescence in the blue dopant BD by the triplet-triplet annihilation TTA or triplet-triplet fusion TTF, increasing the utilization of excitons in the blue light emitting layer and improving efficiency of luminescence.

The first to third sub-light emitting layers BEMLa, BEMLb, and BEMLc of the blue light emitting layer BEML have differences in thickness in addition to the host. The second thickness D2 of the second sub-light emitting layer BEMLb of the intermediate layer is the thickest and the third thickness D3 of the third sub-light emitting layer BEMLc is the thinnest. The first thickness D1 of the first sub-light emitting layer BEMLa is greater than the third thickness D3 and less than the second thickness (D3<D1<D2).

Although the first sub-light emitting layer BEMLa generates light immediately by singlet excitons, excess excitons cannot be used for recombination and accumulate at the interface with the adjacent electron blocking layer EBL or second hole transport layer HTL2, which can cause the lifespan of the light emitting device to be shortened. Therefore, the light emitting display device of the embodiments of the present disclosure prevents a reduction in the lifespan of the light emitting device due to exciton diffusion to the interface with the electron blocking layer EBL or second hole transport layer HTL2 by securing a thickness D2 of a second sub-light emitting layer BEMLb that induces delayed fluorescence by TTA or TTF, in addition to the first sub-light emitting layer BEMLa that generates light immediately, and making the first sub-light emitting layer BEMLa thinner than the second sub-light emitting layer BEMLb (D1<D2). In addition, a second sub-light emitting layer BEMLb having a thickness is capable of securing the balance between immediate and delayed fluorescence in the blue light emitting layer BEML and minimizing or reduce carriers not utilized for recombination in the blue light emitting layer BEML.

The third sub-light emitting layer BEMLc functions to transfer energy to the second sub-light emitting layer BEMLb and to control the speed at which electrons are transferred from the first or second hole-blocking layer HBL1 and HBL2 to the blue light emitting layer BEML, thereby allowing the recombination region to be partially separated from the electron-blocking layer EBL or the second hole-transport layer HTL2.

The thickness of the second blue light emitting layer BEML2 among the first blue light emitting layer BEML1 and the second blue light emitting layer BEML2 is preferably greater than that of the first blue light emitting layer BEML1. Here, the comparison in the thickness between the first and second blue light emitting layers BEML1 and BEML2 can be based on the total thickness of the first to third sub-light emitting layers.

The first green light emitting layer GEML1 and the second green light emitting layer GEML2 can each include a green dopant GD and a green host. The green dopant can be a phosphorescent dopant and/or a fluorescent dopant. The green host can include both a hole-transporting host and an electron-transporting host.

The first red light emitting layer REML1 and the second red light emitting layer REML2 can each include a red dopant GD and a red host. The red dopant RD can be a phosphorescent dopant and/or a fluorescent dopant. The red host can include both a hole-transporting host and an electron-transporting host.

In the light emitting display device, a viewer can view the device not only in a direction normal to a substrate 100 but also at various viewing angles with respect to the substrate 100. When the viewer views the light emitting display device in the direction normal to the substrate 100, the viewing angle is defined as 0°. When the viewer views the light emitting display device, the angle formed between the viewing direction of the viewer and the normal direction of the substrate 100 is defined as the viewing angle. For example, when variations in color coordinates remain within a predetermined range at viewing angles of 45° or within 60°, the light emitting display device can be considered to have excellent viewing-angle characteristics. However, embodiments of the present disclosure are not limited thereto.

Meanwhile, the light emitting display device according to the embodiments of the present disclosure includes a light emitting device including a first color light emitting layer REML1, GEML1, and BEML1 of a first light emitting stack and a second color light emitting layer REML2, GEML2, and BEML2 of a second light emitting stack, the first and second light emitting stacks having at least different vertical phases. When the viewing angle changes, the first color light emitting layer REML1, GEML1, and BEML1 that is relatively farther from the eyes of the viewer can cause a greater change in optical distance than the second color light emitting layer REML2, GEML2, and BEML2 that is relatively closer to the eyes of the viewer. Therefore, in consideration of the change in optical distance depending on the change in viewing angle, the first color light emitting layer REML1, GEML1, and BEML1 that is relatively farther from the eyes of the viewer can be thinner than the second color light emitting layer REML2, GEML2, and BEML2 located thereon, thereby reducing the sensitivity to optical distance change caused by the first color light emitting layer REML1, GEML1, and BEML1.

Additionally, with reference to FIG. 3, thicknesses of the first red light emitting layer REML1 and the second red light emitting layer REML2 can be different from thicknesses of the first green light emitting layer GEML1 and the second green light emitting layer GEML2, and different from thicknesses of the first blue light emitting layer BEML1 and the second blue light emitting layer BEML2. For example, the thicknesses of the first red light emitting layer REML1 and the second red light emitting layer REML2 can be greater than the thicknesses of the first green light emitting layer GEML1 and the second green light emitting layer GEML2. Also, the thicknesses of the first green light emitting layer GEML1 and the second green light emitting layer GEML2 can be greater than the thicknesses of the first blue light emitting layer BEML1 and the second blue light emitting layer BEML2. However, embodiments of the present disclosure are not limited thereto.

Meanwhile, as shown in FIG. 4, the PL (photoluminescence) spectrum of the blue dopant BD included in the first and second blue light emitting layers BEML1 and BEML2 has a narrow half-width compared to the red dopant RD included in the first and second red light emitting layers REML1 and REML2 and the green dopant GD included in the first and second green light emitting layers GEML1 and GEML2.

Each sub-pixel RSP, GSP, BSP exhibits a different EL (electroluminescence) spectrum, defined as the product of the PL spectrum and the out-coupling emittance spectrum, due to the difference in thickness of the different light emitting dopants RD, GD, and BD and the intermediate layers REL, GEL, and BEL. In particular, when the viewing angle changes, the out-coupling emittance spectrum shifts toward a short wavelength, and the blue dopant BD exhibits a large EL spectrum change due to the small shift compared to the red dopant RD and the green dopant GD, so that the change in visual perception can be large in the third sub-pixel BSP when the viewing angle changes. According to an embodiment of the present disclosure, a light emitting display device includes a second blue light emitting layer BEML2 that is relatively thicker than the first blue light emitting layer BEML1 in a third sub-pixel BSP that emits blue light, which is highly sensitive to changes in viewing angle, thereby securing blue light emission efficiency and maintaining lifespan characteristics, while reducing sensitivity to changes in viewing angle and securing viewing angle characteristics.

The first thickness D1 of the first sub-light emitting layer BEMLa including the same material as at least one of the first blue light emitting layer BEML1 and the second blue light emitting layer BEML2 can be no less than twice a third thickness D3 of the third sub-light emitting layer BEMLc and no more than three times the third thickness D3 (2D3≤D1≤3D3). The thickness of the first sub-light emitting layer BEMLa that performs direct luminescence of singlet excitons by immediate luminescence is greater than that of the third sub-light emitting layer BEMLc that has an energy transfer function.

The blue dopant BD can include, for example, a boron-based dopant represented by Formulae 1 to 9 below. However, this is merely an example and the dopant in the embodiments of the present disclosure is not limited to the materials described below. Any fluorescent dopant capable of fluorescence and delayed fluorescence, having an emission peak at a visible wavelength of 420 nm to 495 nm, and having a triplet energy level higher than that of the first and second blue hosts BH1 and BH2 can be substituted.

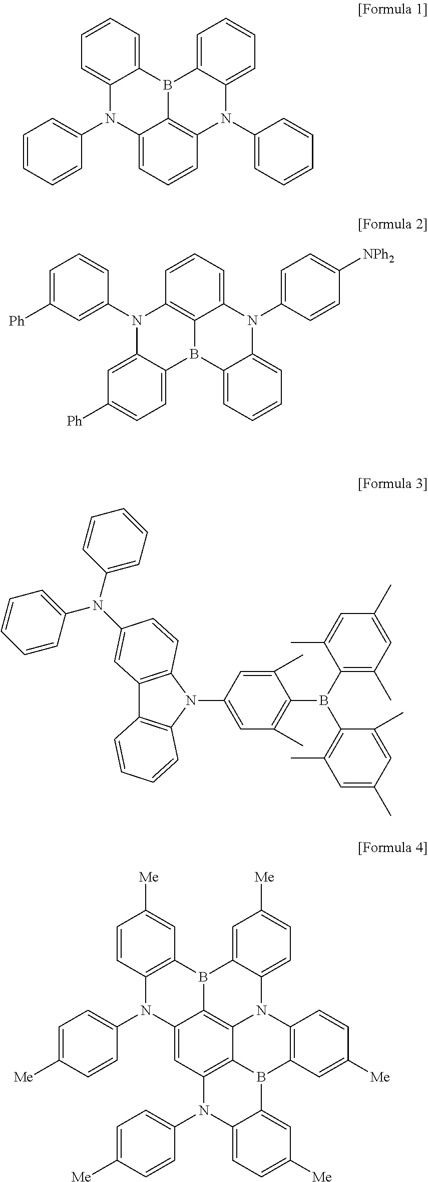

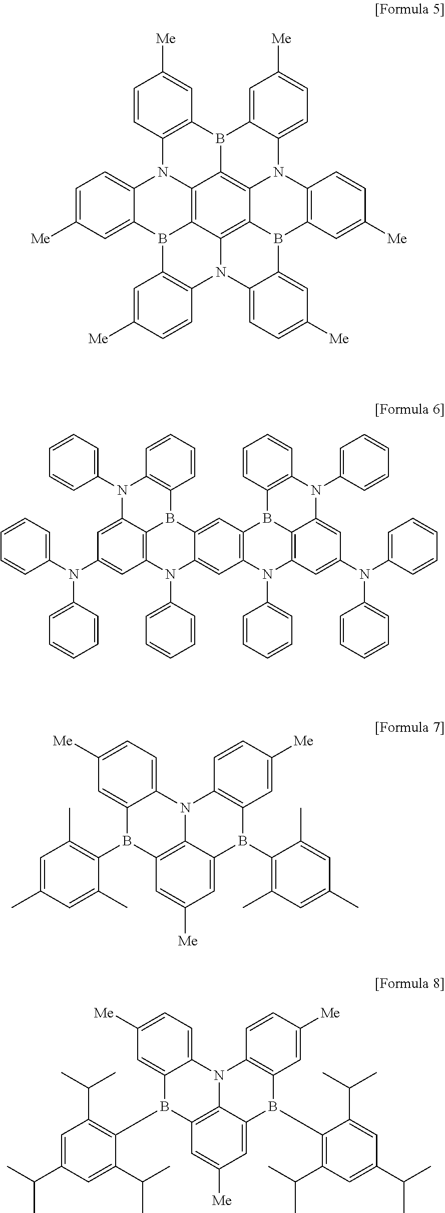

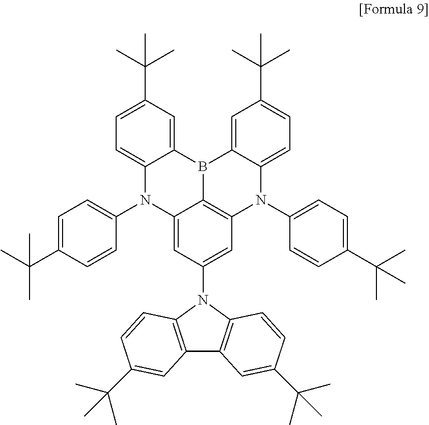 [SMILES: CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C(C)(C)C)cc6c6cc(C(C)(C)C)ccc65)cc2c43)cc1]

In addition, in the light emitting device according to the embodiment of the present disclosure, by changing the substituent in at least a part of any one of the compounds of Formulas 1 to 9, the triplet energy level of the dopant can be adjusted.

Meanwhile, in the first to third sub-pixels RSP, GSP, BSP, the first stack S1 may be different from the second stack S2 in that an electron blocking layer EBL is further disposed under the first red light emitting layer REML1, the first green light emitting layer GEML1, and the first blue light emitting layer BEML1 and above the first hole transport layer HTL1. A second hole transport layer HTL2 is disposed in direct contact under the second red light emitting layer REML2, the second green light emitting layer GEML2, and the second blue light emitting layer BEML2 without an electron blocking layer therebetween. This means that the first stack S1 is closer to the anode (AND, 122) and thus has a faster hole injection speed than the second stack S2, and thus an electron blocking layer EBL that is relatively slower than the first and second hole transport layers HTL1 and HTL2 is further disposed on the first stack S1. The electron blocking layer EBL has a higher LUMO energy level than the hole transport material of the adjacent first hole transport layer HTL1 to confine electrons to each of the first color light emitting layers REML1, GEML1, and BEML1, and can include a hole transport material that has low hole mobility compared to the first hole transport layer HTL1. Preferably, the hole mobility of the first hole transport layer HTL1 can be 1 to 3 orders of magnitude (10 to 1000 times) greater than the hole mobility of the electron blocking layer EBL.

Referring to FIG. 4, the energy band gaps of the first host BH1 and the second host BH2 are described as follows.

The HOMO energy level HOMO1_BH1 of the first host BH1 is higher than the HOMO energy level HOMO_BH2 of the second host BH2 and the LUMO energy level LUMO1_BH1 of the first host BH1 can be higher than the LUMO energy level (LUMO_BH2) of the second host BH2.

The HOMO energy level HOMO_BD of the blue dopant BD is higher than the HOMO energy levels HOMO_BH1 and HOMO_BH2 of the first and second hosts BH1 and BH2 (HOMO_BD>HOMO_BH1, HOMO_BD_>HOMO_BH2). Therefore, since the blue dopant BD has a HOMO energy level similar to that of the adjacent electron blocking layer EBL or second hole transport layer HTL2, recombination occurs in the blue dopant BD with a shallow HOMO level when holes are transferred from the electron blocking layer EBL or the second hole transport layer HTL2 to the blue light emitting layer BEML. In the light emitting display device of the embodiments of the present disclosure, the second sub-light emitting layer BEMLb, which receives energy and carriers from the first sub-light emitting layer BEMLa, is thicker than the first sub-light emitting layer BEMLa, so that a recombination region RZ that performs immediate light emission can be formed in the first sub-light emitting layer BEMLa by a predetermined distance from the interface between the first sub-light emitting layer BEMLa and the electron blocking layer EBL, thereby preventing accumulation of carriers and excitons at the interface between the first sub-light emitting layer BEMLa and the electron blocking layer EBL, and improving the lifespan characteristics.

### *Experimental Examples 1 to 3 (EX1, EX2 and EX3)*

Hereinafter, the characteristics of the blue light emitting layer BEML including the triple sub-light emitting layers of FIG. 3 depending on the thickness of the first sub-light emitting layer BEMLa will be described.

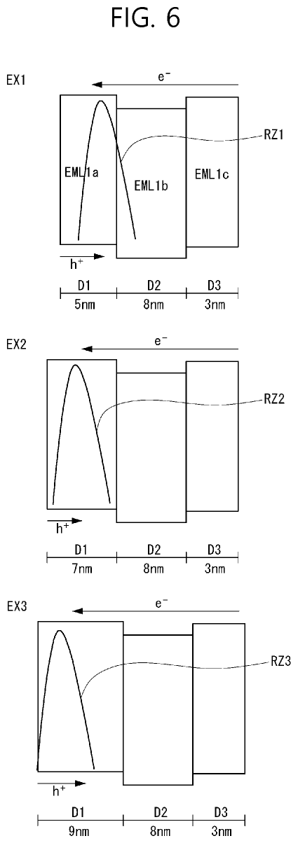

FIG. 6 is a diagram showing the location of the recombination region depending on the thickness of the first sub-light emitting layer of the multiple blue light emitting layer structure in Experimental Examples 1 to 3.

TABLE 1

| | Thickness | | | Device performance | | |
|---|---|---|---|---|---|---|
| | BEMLa | BEMLb | BEMLc | Voltage | | |
| Item | [nm] | [nm] | [nm] | [V] | Efficiency | Lifespan |
| EX1 | 5 | 8 | 3 | Vr | Er | Lr |
| EX2 | 7 | 8 | 3 | Vr + 0.06 | Er*98% | Lr*120% |
| EX3 | 9 | 8 | 3 | V + 0.15 | Er*84% | Lr*77% |

Experimental Examples 1 to 3 EX1, EX2, and EX3 were constructed by sequentially stacking a hole injection layer HIL, a hole transport layer HTL, an electron blocking layer EBL, a blue light emitting layer BEML, a hole blocking layer HBL, an electron transport layer ETL, and an electron injection layer between the anode and the cathode. The blue light emitting layer BEML was configured to include first to third sub-light emitting layers BEMLa, BEMLb, and BEMLc containing different hosts, as shown in FIG. 3. The anode included a reflective electrode formed of a silver alloy and the cathode included an AgMg alloy.

In Experimental Example 1 EX1, the thickness of the first sub-light emitting layer BEMLa was 5 nm, the thickness of the second sub-light emitting layer BEMLb was 8 nm, and the thickness of the third sub-light emitting layer BEMLc was 3 nm. Experimental Example 2 EX2 has the same configuration as Experimental Example 1 EX1 except that the thickness of the first sub-light emitting layer BEMLa was 7 nm, and Experimental Example 3 EX3 has the same configuration as Experimental Example 1 EX1 except that the thickness of the first sub-light emitting layer BEMLa was 9 nm.

The voltage, efficiency, and lifespan characteristics were evaluated based on Experimental Example 1 EX1.

The recombination regions RZ1, RZ2, and RZ3 in Experimental Examples 1 to 3 EX1, EX2 and EX3 of FIG. 6 can be formed on the interface between the first sub-light emitting layer BEMLa and the electron blocking layer, as the thickness of the first sub-light emitting layer BEMLa decreases (see EBL of FIG. 2). In addition, in Experimental Example 2 EX2, it can be seen that the presence of the recombination region RZ2 in the first sub-light emitting layer BEMLa prevents excitons from accumulating at any interface, thereby improving the lifespan characteristics, as shown in Table 1. In addition, although the thickness change of the first sub-light emitting layer BEMLa in Experimental Example 2 EX2 is large compared to Experimental Example 1 EX1, the entire area of the first sub-light emitting layer BEMLa is immediately used for light emission, and there is no carrier accumulation, so that carrier transfer and energy transfer from the first sub-light emitting layer BEMLa to the second sub-light emitting layer BEMLb are easy, there is almost no difference in efficiency Er from Experimental Example 1 EX1, and the increase in driving voltage is also minimal or reduced. Therefore, Experimental Example 2 EX2 has a 120% increase in lifespan compared to Experimental Example 1 EX1 and thus the driving voltage and efficiency characteristics are almost at the same level. In Experimental Example 2 EX2, the peak of the recombination region RZ2 of holes and electrons occur in an intermediate region away from the interfaces between the first and second sub-light emitting layers BEMLa and BEMLb, and tails of the recombination region RZ2 stay within the first sub-light emitting layer BEMLa. Accordingly, the recombination region RZ2 of holes and electrons can be located entirely in the first sub-light emitting layer BEMLa.

In Experimental Example 1 EX1, the peak of recombination region RZ1 of holes and electrons occurs at a location close to the interface between the first and second sub-light emitting layers BEMLa and BEMLb, so that excess excitons are formed at a part of the interface between the first and second sub-light emitting layers BEMLa and BEMLb, and thus the lifespan is relatively shorter than that of Experimental Example 2 EX2. Accordingly, in Experimental Example 1 EX1, the peak of the recombination region RZ1 of holes and electrons occur in an intermediate region close to the interfaces between the first and second sub-light emitting layers BEMLa and BEMLb, and at least one tail of the recombination region RZ1 may be generated in the second sub-light emitting layer BEMLb, not within the first sub-light emitting layer BEMLa.

The recombination region RZ3 in Experimental Example 3 EX3 is completely separated from the second sub-light emitting layer BEMLb, resulting in the recombination region RZ3 localized on the electron blocking layer EBL, leading to severe lifespan degradation, less exciton diffusion throughout the blue light emitting layer BEML, and low efficiency. Accordingly, in Experimental Example 3 EX3, the peak of the recombination region RZ3 of holes and electrons occur in an intermediate region away from the interfaces between the first and second sub-light emitting layers BEMLa and BEMLb, and at least one tail of the recombination region RZ2 is at or immediately adjacent to an edge of the first sub-light emitting layer BEMLa.

Meanwhile, hereinafter, the example structures of FIG. 2 in which the first blue light emitting layer BEML1 and the second blue light emitting layer BEML2 are disposed in different stacks of the third sub-pixel BSP will be described. The first and second blue light emitting layers BEML1 and BEML2 have different driving voltage, efficiency, and lifespan in the multilayer structure because they are disposed in different stacks.

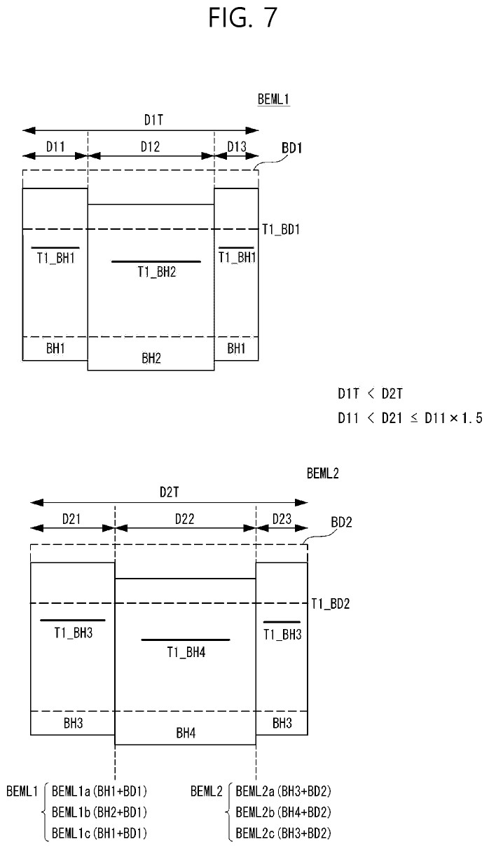

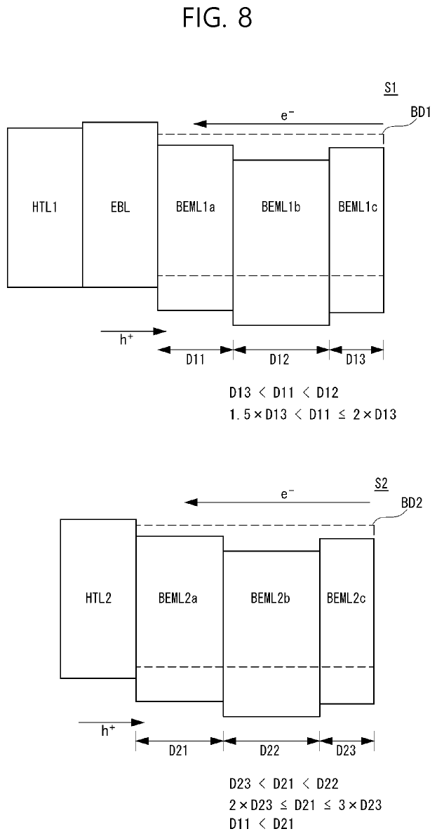

FIG. 7 is an energy band diagram of a first blue light emitting layer and a second blue light emitting layer of a third sub-pixel in a light emitting display device according to an embodiment of the present disclosure. FIG. 8 is an energy band diagram of a hole transport common layer and a blue light emitting layer in the first stack and the second stack.

As shown in FIGS. 7 and 8, each of the first blue light emitting layer BEML1 and the second blue light emitting layer BEML2 include first to third sub-light emitting layers BEML1a/BEML1b/BEML1c, BEML2a/BEML2b, and BEML2c.

The first sub-light emitting layer BEML1a and the third sub-light emitting layer BEML1c of the first blue light emitting layer BEML1 include a first blue host BH1 and a first blue dopant BD1, and the second sub-light emitting layer BEML1b of the first blue light emitting layer BEML1 includes a second blue host BH2 having a triplet energy level lower than that of the first blue host BH1 (T1_BH1<T1_BH2) and the first blue dopant BD1.

The first sub-light emitting layer BEML2a and the third sub-light emitting layer BEML2c of the second blue light emitting layer BEML2 can include a third blue host BH3 and a second blue dopant BD2, and the second sub-light emitting layer BEML2b of the second blue light emitting layer BEML2 can include a fourth blue host BH4 having a lower triplet energy level than the third blue host BH3 and a second blue dopant BD2. The third blue host BH3 can be the same as the first blue host BH1 and the fourth blue host BH4 can be the same as the second blue host BH2. However, this is an example and the second blue light emitting layer BEML2 of the second stack S2 can be a different material from the first blue light emitting layer BEML1 of the first stack S1 as long as the third blue host BH3 has a higher triplet energy level than the fourth blue host BH4.

The first blue dopant BD1 commonly included in the first blue light emitting layer BEML1 and the second blue dopant BD2 commonly included in the second blue light emitting layer BEML2 can be the same or different. When the triplet energy levels between the third and fourth hosts BH3 and BH4 included in the second blue light emitting layer BEML2 and the second blue dopant BD2 are in the relationship T1_BD2>T1_BH3>T1_BH4, they can be replaced with different materials. A triplet energy level T1_BD2 of the second blue dopant BD2 can be higher than the triplet energy levels T1_BH3 and T1 BH4 of the third and fourth hosts BH3 and BH4, respectively.

Here, since the first blue light emitting layer BEML1 of the first stack S1 is more sensitive to viewing angle changes than the second blue light emitting layer BEML2, the thickness DIT of the first blue light emitting layer BEML1 is smaller than the thickness D2T of the second blue light emitting layer BEML2. For example, the thickness D2T of the second blue light emitting layer BEML2 can be greater than the thickness DIT of the first blue light emitting layer BEML1 (DIT<D2T). However, embodiments of the present disclosure are not limited thereto.

The difference in thickness between the first and second blue light emitting layers BEML1 and BEML2 is present in each first sub-light emitting layer BEML1a and BEML2a, and each recombination region can be adjusted. For example, the thickness D11 of the first sub-light emitting layer BEML1a of the first blue light emitting layer BEML1 can be smaller than the thickness D21 of the first sub-light emitting layer BEML2a of the second blue light emitting layer BEML2, and the thickness D21 of the first sub-light emitting layer BEML2a of the second blue light emitting layer BEML2 can be 1.5 times or less than the thickness D11 of the first sub-light emitting layer BEML1a (D11<D21≤D11*1.5). However, embodiments of the present disclosure are not limited thereto.

The HOMO energy level HOMO_BD1 of the first blue dopant BD1 is higher than the HOMO energy levels HOMO_BH1, and HOMO_BH2 of each of the first and second blue hosts BH1 and BH2 (HOMO_BD1>HOMO_BH1, HOMO_BD1>HOMO_BH2), and the HOMO energy level HOMO_BD2 of the second blue dopant BD2 can be higher than the HOMO energy level of each of the third and fourth blue hosts HOMO_BH3 and HOMO_BH4 (HOMO_BD2>HOMO_BH3, HOMO_BD2>HOMO_BH4).

Among the first to third sub-light emitting layers BEML1a, BEML1b and BEML1c of the first blue light emitting layer BEML1, the second sub-light emitting layer BEML1b can be the thickest and the third sub-light emitting layer BEML1c can be the thinnest (D13<D11<D12).

Among the first to third sub-light emitting layers BEML2a, BEML2b, and BEML2c of the second blue light emitting layer BEML2, the second sub-light emitting layer BEML2b can be the thickest and the third sub-light emitting layer BEML2c can be the thinnest (D23<D21<D22).

The thickness D21 of the first sub-light emitting layer BEML2a in the second blue light emitting layer BEML2 can be two to three times the thickness D23 of the third sub-light emitting layer BEML2c (D23*2≤D21≤D23*3).

In the first blue light emitting layer BEML1, the thickness D11 of the first sub-light emitting layer BEML1a can be greater than the thickness D13 of the third sub-light emitting layer BEML1c and can be no more than twice the thickness D13 of the third sub-light emitting layer BEML1c (D13≤D11≤D13*2).

As shown in FIG. 8, in the first stack S1, an electron blocking layer EBL having a lower hole mobility than the first hole transport layer HTL1 is provided in contact with the first blue light emitting layer BEML1, so that, although the thickness D11 of the first sub-light emitting layer BEML1a of the first blue light emitting layer BEML1 is less than the thickness D21 of the second sub-light emitting layer BEML1b of the second blue light emitting layer BEML2, recombination of holes and electrons occurs without localization at the interface between the first sub-light emitting layer BEML1a and the electron blocking layer EBL in the first blue light emitting layer BEML1, and thus a decrease in lifespan can be prevented.

### *Experimental Examples 4 to 9 (EX4, EX5, EX6, EX7, EX8, EX9)*

In the structure of the light emitting display device to which the first and second blue light emitting layers BEML1 and BEML2 of FIGS. 3, 7, and 8 are applied, device performance depending on thickness changes of the first to third sub-light emitting layers of the first and second blue light emitting layers BEML1 and BEML2 was determined through experiments. The thickness of each layer in the following description is an example applied to Experimental examples and the thickness of the layers of the light emitting devices of the light emitting display devices of the embodiments of the present disclosure is not limited thereto and can be changed as needed as long as the thickness relationship with adjacent layers is not limited.

In the following experiments, only the thickness of the first sub-light emitting layer BEML1a and BEML2a among the first to third sub-light emitting layers of the first and second blue light emitting layers BEML1 and BEML2 was changed and the remaining configurations were the same.

The structure of the light emitting device commonly applied to Experimental Example 4 EX4 to Experimental Example 9 EX9 is the same as shown in FIG. 2 and the light emitting devices of the first to third sub-pixels RSP, GSP, BSP are configured in the following process.

Each of the first to third sub-pixels RSP, GSP, and BSP on the substrate is provided with an anode AND including a reflective electrode.

A hole injection layer HIL, a first hole transport layer HTL, and an electron blocking layer EBL are sequentially provided on the anode AND of the first to third sub-pixels RSP, GSP and BSP. The hole injection layer HIL includes a p-type dopant and a hole transport material, and the first hole transport layer HTL includes the same hole transport material as the hole injection layer HIL. The total thickness of the hole injection layer HIL and the first hole transport layer HTL1 is 40.5 nm and the electron blocking layer EBL has a thickness of 3 nm. The electron blocking layer EBL includes a hole transport material having a hole mobility that is 1 to 3 orders of magnitude lower than that of the hole transport material included in the first hole transport layer HTL1.

A first red emitting layer REML1 including a red dopant RD, a hole-transporting host, and an electron-transporting host is formed to a thickness of 36 nm on the electron blocking layer EBL of the first sub-pixel RSP.

A first green light emitting layer GEML1 including a green dopant GD, a hole-transporting host, and an electron-transporting host is formed to a thickness of 30 nm on the electron blocking layer EBL of the second sub-pixel GSP.

A first blue light emitting layer BEML1 including first to third sub-light emitting layers BEML1a, BEML1b, and BEML1c sequentially stacked on the electron blocking layer EBL of the third sub-pixel BSP is formed. In Experimental Example 4 EX4, the first sub-light emitting layer BEML1a is formed to a thickness of 5 nm, including a first blue host BH1 and a blue dopant BD. Experimental Examples 5 and 6 EX5 and EX6 differ in that the thickness of the first sub-light emitting layer BEML1a is 7 nm and 9 nm, respectively.

The second sub-light emitting layer BEML1b of the first blue light emitting layer BEML1 is formed to a thickness of 8 nm including a second blue host BH2 and a blue dopant BD. The third sub-light emitting layer BEML1c is formed to a thickness of 3 nm including a first blue host BH1 and a blue dopant BD.

In the first to third sub-pixels RSP, GSP, and BSP, a first hole-blocking layer HBL1 is provided with a thickness of 8 nm on each of the first color light emitting layers REML1, GEML1, and BEML1, and an n-type charge generation layer NCGL is provided with a thickness of 12 nm.

The p-type charge generation layer PCGL and the second hole transport layer HTL2 are sequentially provided on a n-type charge generation layer NCGL. The total thickness of the p-type charge generation layer PCGL and the second hole transport layer HTL2 is 52 nm. The host of the p-type charge generation layer PCGL and the second hole transport layer HTL2 can include the same hole transport material. The p-type charge generation layer PCGL can further include a p-type dopant.

A first optical compensation layer R′HTL is provided on the second hole transport layer HTL2 of the first sub-pixel RSP. The first optical compensation layer R′HTL is provided with a hole transport material and has a thickness of 54 nm. A second red light emitting layer REML2 including a red dopant RD, a hole-transporting host, and an electron-transporting host is formed to a thickness of 36 nm on the first optical compensation layer R′HTL.

A second optical compensation layer G′HTL is formed on the second hole transport layer HTL2 of the second sub-pixel GSP. The second optical compensation layer G′HTL is formed with a hole transport material and has a thickness of 7 nm. A second green light emitting layer GEML2 including a green dopant GD, a hole transport host, and an electron transport host is formed on the second optical compensation layer G′HTL and has a thickness of 30 nm.

A second blue light emitting layer BEML2 including first to third sub-light emitting layers BEML2a, BEML2b, and BEML2c sequentially stacked is formed on the electron blocking layer EBL of the third sub-pixel BSP. In Experimental Example 7 EX7, the first sub-light emitting layer BEML2a includes a first blue host BH1 and a blue dopant BD and has a thickness of 5 nm. Experimental Examples 8 and 9 EX8 and EX9 differ in that the thickness of the first sub-light emitting layer BEML2a is 7 nm and 9 nm, respectively.

In the first to third sub-pixels RSP, GSP and BSP, a second hole-blocking layer HBL2 is provided with a thickness of 5 nm on each of the second color light emitting layers REML2, GEML2, and BEML2, an electron transport layer ETL is provided with a thickness of 30 nm, and an electron injection layer EIL is provided with a thickness of 2 nm.

A cathode CAT is formed to a thickness of 15 nm on the electron injection layer EIL using AgMg and a capping layer CPL is then formed to a thickness of 65 nm.

Meanwhile, among the first and second stacks S1 and S2, the first sub-pixel RSP and the second sub-pixel GSP have a relatively long resonance distance between the anode AND and the cathode CAT compared to the third sub-pixel BSP and thus exhibit microcavity characteristics. Furthermore, the first sub-pixels RSP and the second sub-pixel GSP have first and second optical compensation layers R′HTL and G′HTL to secure red and green cavity characteristics, respectively. The first and second optical compensation layers R′HTL and G′HTL are disposed on the second stack S2, which is closer to the eyes of the viewer and therefore relatively less sensitive to changes in viewing angle.

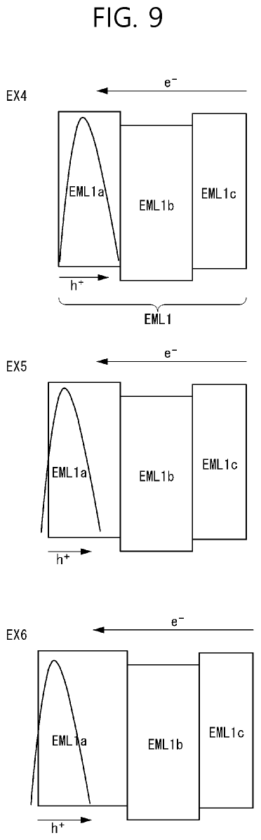

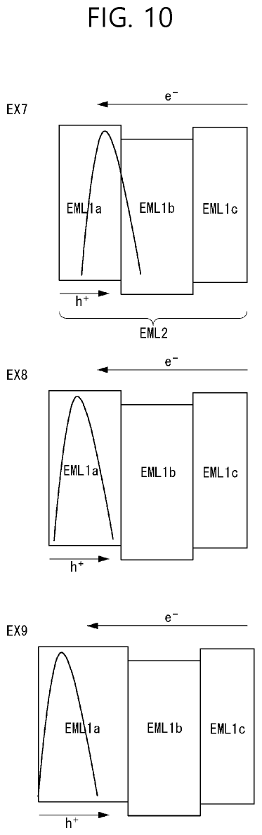

FIG. 9 shows the location of recombination regions formed depending on the thickness of the first sub-light emitting layer in the first blue light emitting stack in Experimental Examples 4 to 6. FIG. 10 shows the location of recombination regions formed depending on the thickness of the first sub-light emitting layer in the second blue light emitting stack in Experimental Examples 7 to 9.

In Experimental Examples 4 to 6 EX4, EX5 and EX6 of Table 2 and FIG. 9, the thicknesses of the first to third sub-light emitting layers of the second blue light emitting layer BEML2 were 7 nm, 8 nm, and 3 nm, respectively. In Experimental Examples 7 to 9 EX7, EX8 and EX9 of Table 3 and FIG. 10, the thicknesses of the first to third sub-light emitting layers of the first blue light emitting layer BEML1 were 7 nm, 8 nm, and 3 nm, respectively.

Based on the case in which the thicknesses of the first to third sub-light emitting layers of the first and second blue light emitting layers BEML1 and BEML2 are 7 nm, 8 nm, and 3 nm, respectively, Table 2 shows the device performance depending on thickness variation of the first sub-light emitting layer BEML1a of the first blue light emitting layer BEML1, and Table 3 shows the device performance depending on the thickness variation of the first sub-light emitting layer BEML2a of the second blue light emitting layer BEML2.

TABLE 2

| | First blue light emitting | Second blue light emitting | Device performance | | |
|---|---|---|---|---|---|
| | layer thickness[nm] | layer thickness[nm] | Voltage | | |
| Item | BEML1a/BEML1b/BEML1c | BEML2a/BEML2b/BEML2c | [V] | Efficacy | Lifespan |
| EX4 | 5/8/3 | 7/8/3 | Vr1 − 0.04 | Er1*104% | Lr1*105% |
| EX5 | 7/8/3 | 7/8/3 | Vr1 | Er1 | Lr1 |
| EX6 | 9/8/3 | 7/8/3 | Vr1 + 0.06 | Er1*96% | Lr1*97% |

TABLE 3

| | First blue light emitting | Second blue light emitting | Device performance | | |
|---|---|---|---|---|---|
| | layer thickness[nm] | layer thickness[nm] | Voltage | | |
| Item | BEML1a/BEML1b/BEML1c | BEML2a/BEML2b/BEML2c | [V] | Efficacy | Lifespan |
| EX7 | 7/8/3 | 5/8/3 | Vr1 − 0.06 | Er1*102% | Lr1*83% |
| EX8 | 7/8/3 | 7/8/3 | Vr1 | Er1 | Lr1 |
| EX9 | 7/8/3 | 9/8/3 | Vr1 + 0.09 | Er1*86% | Lr1*64% |

Like Experimental Examples 4 to 6 EX4, EX5 and EX6 of Table 2 and FIG. 9, when the thickness of the first sub-light emitting layer BEML1a in the first blue light emitting layer BEML1 changes, in Experimental Example 4 EX4 where the thickness is smaller than that of the first sub-light emitting layer BEML2a of the second light emitting layer BEML2, a complete recombination region is formed in the first sub-light emitting layer BEML1a and the effects of reduced driving voltage, maximum efficiency, and increased lifespan can be secured. This is because, in the first stack S1, the first blue light emitting layer BEML1 is in contact with the hole-transporting common layer, which is an electron-blocking layer with low hole mobility. By controlling the movement speed of holes transferred to the first blue light emitting layer BEML1, through the electron-blocking layer, the recombination region in the thin first sub-light emitting layer BEML1a may be shifted to a predetermined extent to and thus the recombination region is disposed in the first sub-light emitting layer BEML1a of the first blue light emitting layer BEML1 without localization at a specific interface.

Comparing Experimental Examples 7 to 9 EX7, EX8 and EX9 in Table 3 and FIG. 10, it can be seen that Experimental Example 8 EX8, where the thickness of the first sub-light emitting layer BEML2a in the second blue light emitting layer BEML2 was 7 nm, exhibited excellent voltage, efficiency, and lifespan characteristics.

As can be seen from Tables 2 and 3 and FIGS. 9 and 10, the voltage, efficiency, and lifespan are improved when, in Experimental Example 4 EX4, the second sub-light emitting layer BEML1b in the first blue light emitting layer BEML1 is the thickest and the third sub-light emitting layer BEML1c is the thinnest, and the second sub-light emitting layer BEML2b in the second blue light emitting layer BEML2 is the thickest and the third sub-light emitting layer BEML2c is the thinnest, and the thickness of the first sub-light emitting layer BEML2a of the second blue light emitting layer BEML2 is greater than the thickness of the first sub-light emitting layer BEML1a of the first blue light emitting layer BEML2.

Meanwhile, Experimental Example 5 EX5 of Table 2 and Experimental Example 8 EX8 of Table 3 have the same configuration.

Herein, the viewing angle characteristics were determined while varying the thickness of the first sub-light emitting layer BEML1a and BEML2a among the first blue light emitting layer BEML1 of the first stack S1 and the second blue light emitting layer BEML of the second stack S2 through optical simulation.

In addition to Experimental Examples 4 to 9 EX4 to EX9 described in Tables 2 and 3, Experimental Example 10 EX10 where the thickness of the first sub-light emitting layer BEML1a of the first blue light emitting layer BEML1 is 3 nm and Experimental Example 11 EX11 where the thickness of the first sub-light emitting layer BEML2a of the second blue light emitting layer BEML2 is 3 nm are added.

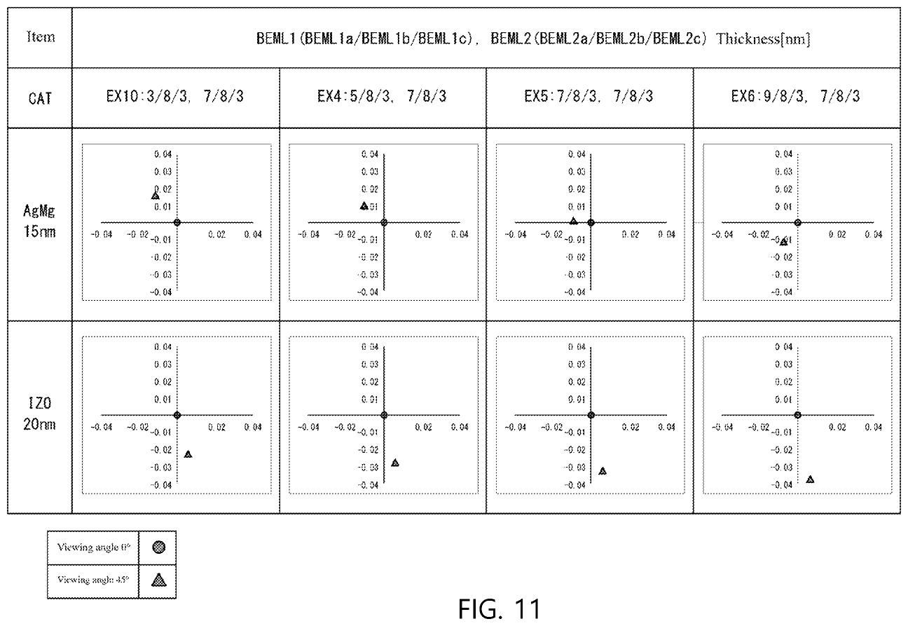

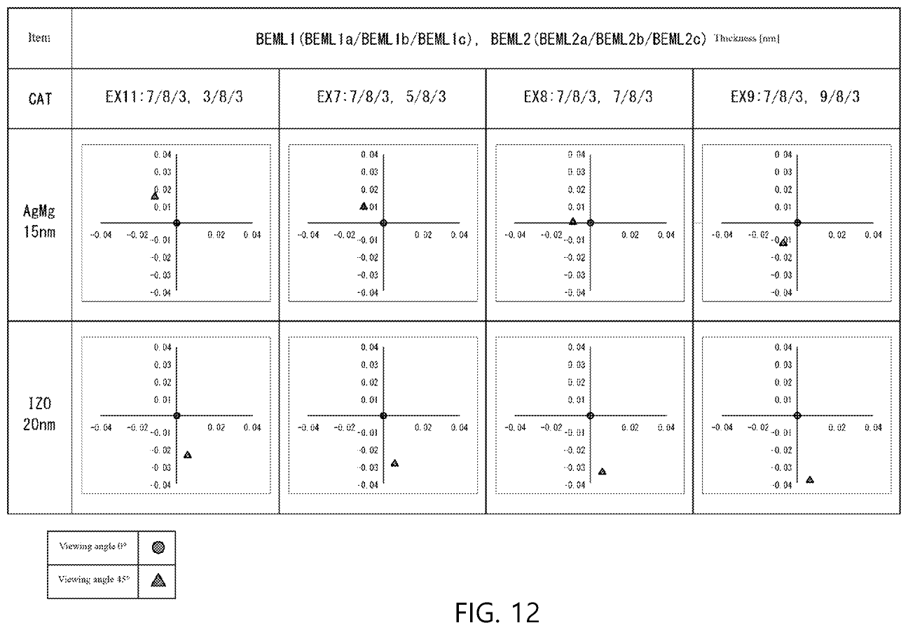

FIG. 11 shows the viewing angle characteristics obtained by varying the thickness of the first sub-light emitting layer of the first blue light emitting layer when the cathode is formed of AgMg with a thickness of 15 nm and when the cathode is formed of IZO with a thickness of 20 nm. FIG. 12 shows the viewing angle characteristics obtained by varying the thickness of the first sub-light emitting layer of the second blue light emitting layer when the cathode is formed of AgMg with a thickness of 15 nm and when the cathode is formed of IZO with a thickness of 20 nm.

FIG. 11 shows that the thickness of the first sub-light emitting layer BEML1a of the first blue light emitting layer BEML1 changes to 3 nm, 5 nm, 7 nm, and 9 nm, and the second sub-light emitting layer BEML1b and the third sub-light emitting layer BEML1c of the first blue light emitting layer BEML1 have a common thickness of 8 nm and 3 nm, respectively. In addition, the second blue light emitting layer BEML2 has the first to third sub-light emitting layers BEML2a, BEML2b, and BEML2c having thicknesses of 7 nm, 8 nm, and 3 nm, respectively.

In each experimental example, viewing angle characteristics were evaluated at a viewing angle of 0° and 45°. Viewing angle characteristics were evaluated by the change in white color coordinates when the light emitting devices of the first to third sub-pixels RSP, GSP, and BSP were turned on. An upward shift in the color coordinates indicates a greenish color change, while a downward shift indicates a blueish color change.

Regarding the thickness change of the first sub-light emitting layer BEML1a of the first blue light emitting layer BEML1, it can be seen that the blueish color change is greater for a cathode that is a light-transmitting electrode, such as IZO, than for a cathode that is a reflective-transmitting electrode, such as AgMg.

FIG. 12 shows that the thickness changes of the first sub-light emitting layer BEML2a of the second blue light emitting layer BEML2 are 3 nm, 5 nm, 7 nm, and 9 nm, and the second sub-light emitting layer BEML2b and the third sub-light emitting layer BEML2c of the second blue light emitting layer BEML2 have a common thickness of 8 nm and 3 nm, respectively. In addition, the first blue light emitting layer BEML1 has the first to third sub-light emitting layers BEML1a, BEML1b, and BEML1c having thicknesses of 7 nm, 8 nm, and 3 nm, respectively.

As can be seen from FIG. 12, the thickness change of the first sub-light emitting layer BEML2a of the second blue light emitting layer BEML2 causes a color similar to the thickness change of the first sub-light emitting layer BEML1a of the first blue light emitting layer BEML1 of FIG. 11.

In consideration of the viewing angle perspective, the light-transmitting cathode (IZO 20 nm) minimizes or reduces color changes due to changes in viewing angle when the thickness of the first sub-light emitting layers BEML1a and BEML2a of each of the first blue light emitting layer BEML1 and the second blue light emitting layer BEML2 is minimized or reduced. However, in the light emitting display device according to the embodiment of the present disclosure, in addition to the viewing angle, the driving voltage, efficiency, and lifespan characteristics can be considered together to make the second blue light emitting layer BEML2 of the second stack S2 thicker than the first blue light emitting layer BEML1.

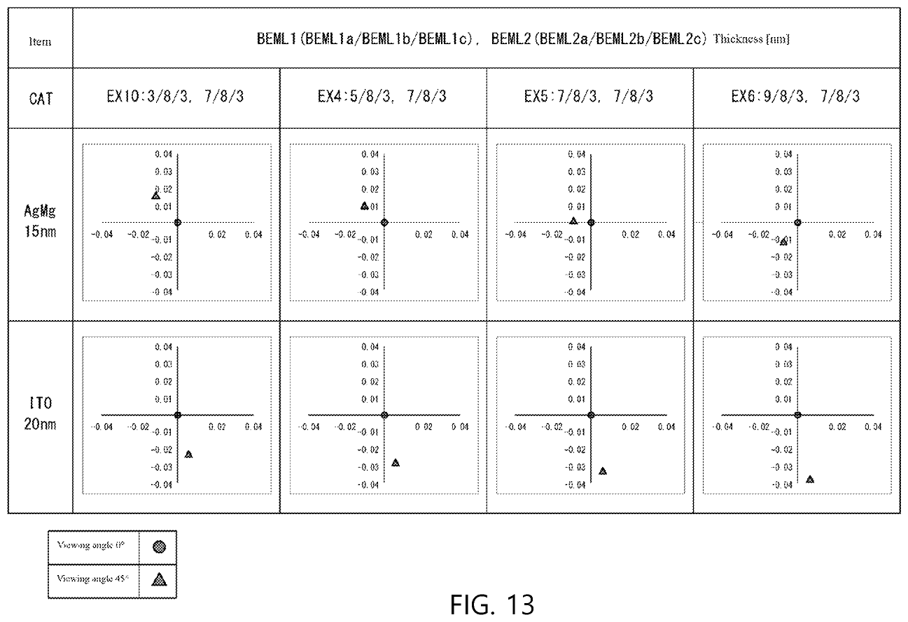

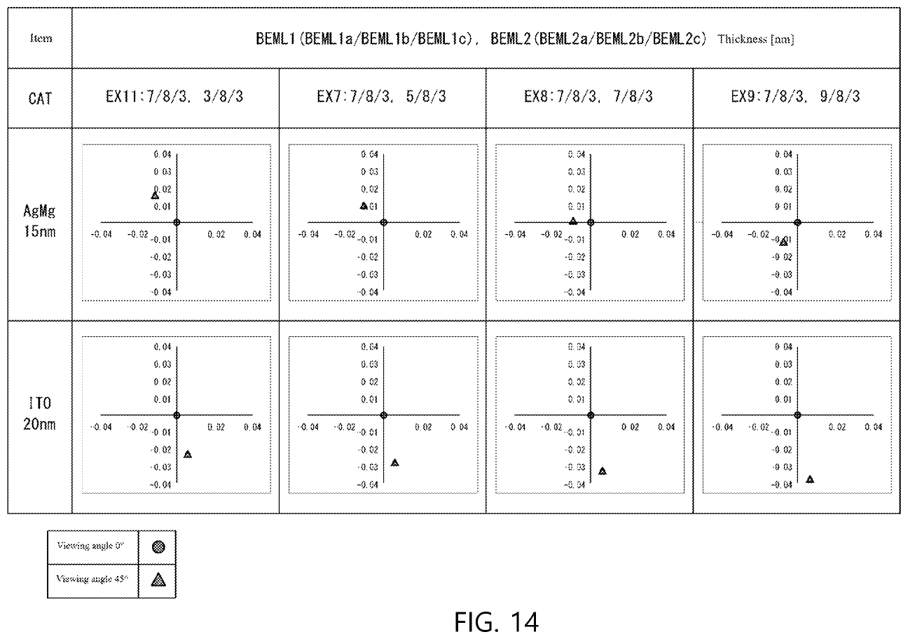

FIG. 13 shows the viewing angle characteristics obtained by varying the thickness of the first sub-light emitting layer of the first blue light emitting layer when the cathode is formed of AgMg with a thickness of 15 nm and when the cathode is formed of ITO with a thickness of 20 nm. FIG. 14 shows the viewing angle characteristics obtained by varying the thickness of the first sub-light emitting layer of the second blue light emitting layer when the cathode is formed of AgMg with a thickness of 15 nm and when the cathode is formed of ITO with a thickness of 20 nm.

Referring to FIGS. 13 and 14, the viewing angle characteristics when ITO is used as the cathode are similar to the viewing angle characteristics when IZO is used as the cathode in FIGS. 11 and 12 described above.

In terms of viewing angle, when the thickness of each of the first blue light emitting layer BEML1 and the second blue light emitting layer BEML2 is minimized or reduced, the color change depending on the viewing angle change is minimized or reduced. However, in the light emitting display device according to the embodiment of the present disclosure, in addition to the viewing angle, the thickness of the second blue light emitting layer BEML2 is secured to a predetermined level compared to the first blue light emitting layer BEML1, in consideration of the driving voltage, efficiency, and lifespan characteristics, so that blue efficiency and lifespan can be secured in the third sub-pixel that emits blue, and the driving voltage can be set to a predetermined level or lower.

The experiment in Table 4 was performed to evaluate the difference in doping concentration of blue dopant in the first to third sub-light emitting layers BEML1a/BEML1b/BEML1c and BEML2a/BEML2b/BEML2c of the first blue light emitting layer BEML1 of the first stack S1 and the second blue light emitting layer BEML2 of the second stack S2.

TABLE 4

| | First blue light emitting | Second blue light emitting | | | |
|---|---|---|---|---|---|
| | layer thickness(nm)/[BD1 | layer thickness (nm)/[BD2 | Device performance | | |
| | concentration] | concentration] | Voltage | | |
| Item | BEML1a/BEML1b/BEML1c | BEML2a/BEML2b/BEML2c | [V] | Efficacy | Lifespan |
| EX5 | 7[1%]/8[1%]/3[1%] | 7[1%]/8[1%]/3[1%] | Vr1 | Er1 | Lr1 |
| EX12 | 7[1.5%]/8[1.5%]/3[1.5%] | 7[1%]/8[1%]/3[1%] | Vr1 − 0.03 | Er1*99% | Lr1*113% |
| EX13 | 7[1%]/8[1%]/3[1%] | 7[1.5%]/8[1.5%]/3[1.5%] | Vr1 − 0.04 | Er1*98% | Lr1*101% |

As shown in Table 4, when the doping concentration of the first blue dopant BD1 of the first blue light emitting layer BEML1 of the first stack S1 is greater than the doping concentration of the second blue dopant BD2 of the second blue light emitting layer BEML2, the driving voltage is lowered and the lifespan is improved.

The optical simulation of the experiments used herein is the “1D simulation (LG Display)” program.

Hereinafter, a light emitting display device according to another embodiment of the present disclosure will be described.

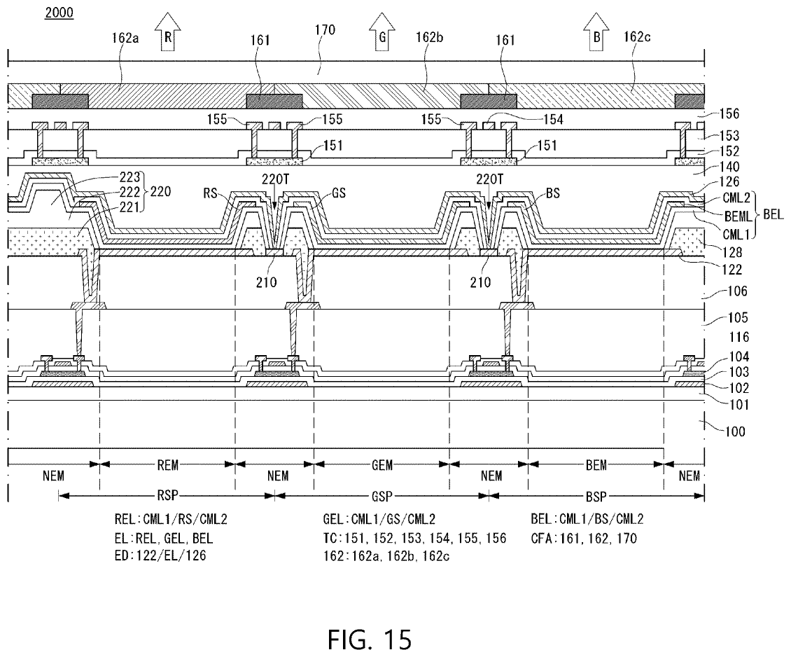

FIG. 15 is a cross-sectional view illustrating a light emitting display device according to another embodiment of the present disclosure.

The light emitting display device 2000 according to FIG. 15 differs from the light emitting display device 1000 shown in FIG. 2 in the configuration of the bank 220 and the connection structure between the auxiliary electrode 210 and the cathode 126.

The bank 220 can include a first light-shielding bank 221 and a second light-transmitting bank 222. Furthermore, the bank 220 between adjacent sub-pixels RSP, GSP, BSP can have a trench 220T extending from the surface to a predetermined depth, so that the side leakage current can be minimized or reduced by lengthening the side path of the adjacent sub-pixels RSP, GSP, BSP. In some cases, at least a portion of the first and second common layers CML1 and CML2 can be disconnected in the trench 220T. In this case, the lateral leakage current prevention effect is further improved.

In some cases, an auxiliary electrode can be provided on the lower side of the trench 220T, the trench 220T can be provided deep enough to expose the auxiliary electrode 210, and the cathode 126 can be connected to the auxiliary electrode 210 in the trench 220T, thereby providing a cathode 126 connection area within the display area AA where the sub-pixels RSP, GSP, BSP are disposed, and reducing the resistance of the cathode 126. In particular, when the cathode 126 includes a light-transmitting electrode, the resistance of the cathode 126 can be reduced by connecting the auxiliary electrode 210 to the cathode 126, thereby uniformizing the voltage characteristics of the cathode 126 in the display area AA and uniformizing the luminance characteristics of the display area AA.

The bank 220 can further include a spacer 223 having a greater height than, for example, the second bank 222, so that the spacer 223 can protect the lower configuration with respect to the deposition mask used when forming the intermediate layer REL, GEL, and BEL of each sub-pixel RSP, GSP, and BSP.

Meanwhile, in the light emitting display device 2000 of FIG. 15, the first to third sub-pixels RSP, GSP, BSP have a configuration in which at least two light emitting stacks S1 and S2 are stacked, as described with reference to FIGS. 1 to 5. Each of the first to third sub-pixels RSP, GSP, BSP can include a first common layer CML1, a color light emitting pattern portion RS, GS, BS, and a second common layer CML2 between the anode (122, AND) and the cathode (126, CAT) of the light emitting device. The first and second common layers CML1 and CML2 can be removed at the portion where the cathode 126 and the auxiliary electrode 210 are connected.

Each color light emitting pattern section RS, GS, BS includes a first color light emitting layer REML1, GEML1, and BEML1, a third common layer CML3, and a second color light emitting layer REML2, GEML2, and BEML2, and the first color light emitting layer REML1, GEML1, and BEML1, and the second color light emitting layer REML2, GEML2, and BEML2 have shapes independently provided in the first to third sub-pixels RSP, GSP, and BSP.

As shown in FIGS. 3, 7, and 8, the first blue light emitting layer BEML1 provided in the third sub-pixel BSP includes first to third sub-light emitting layers BEML1a, BEML1b, and BEML1c having different hosts BH1 and BH2 alternately, and the second blue light emitting layer BEML2 includes first to third sub-light emitting layers BEML2a, BEML2b, and BEML2c having different hosts BH3 and BH4 alternately. The first to third sub-light emitting layers of the first and second blue light emitting layers BEML1 and BEML2 can be light emitting layers of each stack, such that the second sub-light emitting layer BEML1b and BEML2b, which is an intermediate layer, can be the thickest, and the third sub-light emitting layer BEML1c and BEML2c, which is the last layer, can be the thinnest. In addition, by ensuring that the thickness of the first sub-light emitting layer BEML2a, which is the second blue light emitting layer BEML2, is greater than that of the first sub-light emitting layer BEML1a of the first blue light emitting layer BEML1 in contact with the relatively slow electron blocking layer EBL, high efficiency and long lifespan can be achieved without a significant change in the driving voltage required for blue light emission in a multiple stack structure, and at the same time, viewing angle characteristics can be improved.

The light emitting display device of the embodiments of the present disclosure has a light emitting device including multiple light emitting layers that can improve efficiency, reduce driving voltage, and improve lifespan in at least some sub-pixels.

As is apparent from the above description, a light emitting device display device according to an embodiment of the present disclosure includes a plurality of light emitting layers each provided in first and second light emitting stacks overlapping each other in at least a part of sub-pixels, wherein the thickness relationship between the light emitting layers is defined such that the recombination region of holes and electrons is spaced from the interface between the light emitting layer and the common layer, thereby preventing a decrease in the lifespan caused by carrier or exciton accumulation at the light emitting layer interface.

An embodiment of the present disclosure provides a light emitting display device, in which a plurality of light emitting layers of each stack includes a plurality of sub-light emitting layers with different hosts, so that the triplet-triplet-annihilation TTA efficiency in the second sub-light emitting layer, which is the thickest layer, is enhanced and thus exciton utilization within the light emitting layer and light emitting efficiency is enhanced.

An embodiment of the present disclosure provides a light emitting display device wherein, in a multi-light emitting layer, a first sub-light emitting layer adjacent to a hole transporting common layer includes a first host having a smaller HOMO energy level difference with a dopant, and a second sub-light emitting layer includes a second host having a HOMO energy level lower than that of the first host, so that hole transfer from the first sub-light emitting layer to the second sub-light emitting layer is facilitated and trapping of holes is prevented at an interface between the hole-transporting common layer and the light emitting layer.

An embodiment of the present disclosure provides a light emitting display device that includes a plurality of light emitting stacks in each sub-pixel in a top-emission manner to improve luminous efficiency and, in a structure having a plurality of stacked light emitting layers, to minimize or reduce color shift due to changes in viewing angle, thereby providing uniform visual perception regardless of variations in a viewing angle.

An embodiment of the present disclosure provides a light emitting display device that exhibits improved lifespan through a difference in dopant concentration included in light emitting layers of different stacks.

The light emitting devices and light emitting display devices according to embodiments of the present disclosure are capable of improving the efficiency of the light emitting layer, thereby reducing the driving voltage and improving the lifespan. Therefore, the light emitting devices and light emitting display devices have the significance of being continuously applicable and are capable of achieving ESG (environmental/social/governance) goals.

The effects achievable through the present disclosure are not limited to the above-mentioned effects, and various other effects can be directly or implicitly disclosed in the above detailed description of the present disclosure.

A light emitting display device according to one embodiment of the present disclosure can comprise a substrate comprising a first subpixel, a second subpixel, and a third sub-pixel, a transistor at each of the first to third sub-pixels on the substrate, a planarization layer on the transistor, a first light emitting device, a second light emitting device, and a third light emitting device on the planarization layer, the first, second, and third light emitting devices emitting red, green, and blue light, respectively, at the first to third sub-pixels and an encapsulation layer over the first to third light emitting devices.

Each of the first to third light emitting devices can comprise an anode and a cathode facing each other, and a charge generation layer between the anode and the cathode.

The third light emitting device can comprise a first blue light emitting stack comprising a first blue light emitting layer between the anode and the charge generation layer, and a second blue light emitting stack comprising a second blue light emitting layer between the charge generation layer and the cathode. Each of the first blue light emitting layer and the second blue light emitting layer can comprise a plurality of sub-light emitting layers. A thickness of the second blue light emitting layer can be greater than a thickness of the first blue light emitting layer.

In a light emitting display device according to one embodiment of the present disclosure, the sub-light emitting layers of the first blue light emitting layer and the second blue light emitting layer each can have different hosts at vertically adjacent interfaces.

In each of the first blue light emitting layer and the second blue light emitting layer can comprise first to third sub-light emitting layers.

The first sub-light emitting layer and the third sub-light emitting layer of the first blue light emitting layer can comprise a first blue host and a first blue dopant, and the second sub-light emitting layer of the first blue light emitting layer can comprise a second blue host having a lower triplet energy level than the first blue host, and the first blue dopant.

The first sub-light emitting layer and the third sub-light emitting layer of the second blue light emitting layer can comprise a third blue host and a second blue dopant, and the second sub-light emitting layer of the second blue light emitting layer can comprise a fourth blue host having a lower triplet energy level than the third blue host, and the second blue dopant.

A HOMO energy level of the first blue dopant can be higher than a HOMO energy level of each of the first and second blue hosts.

A HOMO energy level of the second blue dopant can be higher than a HOMO energy level of each of the third and fourth blue hosts.

In a light emitting display device according to one embodiment of the present disclosure, among the first to third sub-light emitting layers of the first blue light emitting layer, the second sub-light emitting layer can be thickest and the third sub-light emitting layer can be thinnest. Among the first to third sub-light emitting layers of the second blue light emitting layer, the second sub-light emitting layer can be thickest and the third sub-light emitting layer can be thinnest.

In a light emitting display device according to one embodiment of the present disclosure, a thickness of the first sub-light emitting layer in the second blue light emitting layer can be two to three times a thickness of the third sub-light emitting layer.

In a light emitting display device according to one embodiment of the present disclosure, in the first blue light emitting layer, the thickness of the first sub-light emitting layer can be greater than that of the third sub-light emitting layer and can be no more than twice the thickness of the third sub-light emitting layer.

In a light emitting display device according to one embodiment of the present disclosure, the first sub-light emitting layer of the first blue light emitting layer can be thinner than the first sub-light emitting layer of the second blue light emitting layer.

In a light emitting display device according to one embodiment of the present disclosure, the thickness of the first sub-light emitting layer of the second blue light emitting layer can be greater than the thickness of the first sub-light emitting layer of the first blue light emitting layer and is no more than 1.5 times the thickness of the first sub-light emitting layer of the first blue light emitting layer.

In a light emitting display device according to one embodiment of the present disclosure, a concentration of the first blue dopant in the first blue light emitting layer can be greater than a concentration of the second blue dopant in the second blue light emitting layer.

In a light emitting display device according to one embodiment of the present disclosure, the first light emitting device can comprise a first red light emitting layer between the anode and the charge generation layer and a second red light emitting layer between the charge generation layer and the cathode, the second light emitting device can comprise a first green light emitting layer between the anode and the charge generation layer and a second green light emitting layer between the charge generation layer and the cathode. And the first red light emitting layer can overlap the second red light emitting layer and can be horizontally spaced from the first blue light emitting layer.

In a light emitting display device according to one embodiment of the present disclosure, the first red light emitting layer, the first green light emitting layer, and the first blue light emitting layer can be in contact with an electron blocking layer commonly provided at the first to third sub-pixels, and the second blue light emitting layer can be in contact with a hole transport layer.

The light emitting display device can further comprise a first optical compensation layer between the hole transport layer and the second red light emitting layer, and a second optical compensation layer between the hole transport layer and the second green light emitting layer.

A light emitting display device according to one embodiment of the present disclosure can further comprise a first common layer between the anode and the first blue light emitting layer; and a second common layer between the second blue light emitting layer and the cathode.

The first common layer and the second common layer can extend horizontally continuously across the first light emitting device and the second light emitting device.

In a light emitting display device according to one embodiment of the present disclosure, the first blue light emitting layer can contact an electron blocking layer on a surface of the first blue light emitting layer facing the anode, and the second blue light emitting layer can contact a hole transport layer on a surface of the second blue light emitting layer facing the charge generation layer.

In a light emitting display device according to one embodiment of the present disclosure, a hole mobility of the hole transport layer can be 1 to 3 orders greater than a hole mobility of the electron blocking layer.

A light emitting display device according to one embodiment of the present disclosure can further comprise a capping layer between the cathode and the encapsulation layer.

The capping layer can be thicker than the cathode.

In a light emitting display device according to one embodiment of the present disclosure, each of the first light emitting device, the second light emitting device, and the third light emitting device can have an emission region defined by a bank on the planarization layer.

Each of the first blue light emitting layer and the second blue light emitting layer can have an edge overlapping the bank.

A light emitting display device according to one embodiment of the present disclosure can comprise a touch electrode on the encapsulation layer. The touch electrode can overlap the bank.

A light emitting display device according to one embodiment of the present disclosure can further comprise a color filter on the touch electrode. The color filter can comprise a red color filter overlapping the first light emitting device, a green color filter overlapping the second light emitting device, and a blue color filter overlapping the third light emitting device.

A light emitting display device according to one embodiment of the present disclosure can further comprise a plurality of inorganic insulating layers between the substrate and the thin film transistor.

In a light emitting display device according to one embodiment of the present disclosure, the first blue light emitting layer may comprise a boron-based fluorescent dopant having an emission peak at a wavelength of 420 nm to 495 nm.

In a light emitting display device according to one embodiment of the present disclosure, the charge generation layer may comprise an n-type charge generation layer adjacent to the first blue light emitting stack and a p-type charge generation layer adjacent to the second blue light emitting stack.

In a light emitting display device according to one embodiment of the present disclosure, the bank may comprise a light-shielding bank and a light-transmitting bank.

A light emitting display device according to one embodiment of the present disclosure can further comprise an auxiliary electrode electrically connected to the cathode through a trench provided in the bank.

In a light emitting display device according to one embodiment of the present disclosure, the anode may comprise a reflective electrode having a laminated structure of indium tin oxide (ITO) and an APC (Ag/Pd/Cu) alloy.

A light emitting display device according to one embodiment of the present disclosure may comprise a substrate having at least a blue sub-pixel and a light emitting device at the blue sub-pixel and including an anode, a cathode, and a first blue light emitting stack and a second blue light emitting stack separated by a charge generation layer. Each of the first and second blue light emitting stacks may comprise a first sub-light emitting layer, a second sub-light emitting layer, and a third sub-light emitting layer. The second sub-light emitting layer may comprise a host having a lower triplet energy level than a host of the first sub-light emitting layer to induce delayed fluorescence via triplet-triplet annihilation. A thickness of the second blue light emitting stack may be greater than a thickness of the first blue light emitting stack.

In a light emitting display device according to one embodiment of the present disclosure, the first sub-light emitting layer may be disposed closer to the anode than the second and third sub-light emitting layers, and a recombination region of holes and electrons is entirely located within the first sub-light emitting layer.

In a light emitting display device according to one embodiment of the present disclosure, the first sub-light emitting layer and the third sub-light emitting layer may include a same host material.

In a light emitting display device according to one embodiment of the present disclosure, the first blue light emitting stack may be in contact with an electron blocking layer having a hole mobility at least 10 times lower than a hole mobility of a hole transport layer in contact with the second blue light emitting stack.

In a light emitting display device according to one embodiment of the present disclosure, a dopant concentration in the first blue light emitting stack may be higher than a dopant concentration in the second blue light emitting stack.

In a light emitting display device according to one embodiment of the present disclosure, the cathode may comprise a transparent conductive material and may be electrically connected to an auxiliary electrode disposed on a same layer as a connection electrode of a transistor of the light emitting device.

While the present disclosure has been described above, the present disclosure is not limited to the above-described embodiments and the accompanying drawings, and it will be apparent to those skilled in the art that various alterations, modifications, and changes can be made without departing from the technical spirit of the disclosure.

What is claimed is:

1. A light emitting display device comprising:
a substrate comprising a first subpixel, a second subpixel, and a third sub-pixel;
transistors respectively at the first to third sub-pixels on the substrate;
a planarization layer on the transistors;
a first light emitting device, a second light emitting device, and a third light emitting device on the planarization layer, the first, second, and third light emitting devices configured to emit red, green, and blue light, respectively, at the first to third sub-pixels; and
an encapsulation layer over the first to third light emitting devices, wherein:
each of the first to third light emitting devices comprises an anode and a cathode facing each other, and a charge generation layer between the anode and the cathode,
wherein the third light emitting device comprises a first blue light emitting stack comprising a first blue light emitting layer between the anode and the charge generation layer, and a second blue light emitting stack comprising a second blue light emitting layer between the charge generation layer and the cathode,
wherein each of the first blue light emitting layer and the second blue light emitting layer comprises a plurality of sub-light emitting layers, and
wherein a thickness of the second blue light emitting layer is greater than a thickness of the first blue light emitting layer.

2. The light emitting display device according to claim 1, wherein the sub-light emitting layers of the first blue light emitting layer and the second blue light emitting layer have different hosts at vertically adjacent interfaces.

3. The light emitting display device according to claim 1, wherein each of the first blue light emitting layer and the second blue light emitting layer comprises first to third sub-light emitting layers,
wherein the first sub-light emitting layer and the third sub-light emitting layer of the first blue light emitting layer comprise a first blue host and a first blue dopant,
wherein the second sub-light emitting layer of the first blue light emitting layer comprises a second blue host having a lower triplet energy level than the first blue host, and the first blue dopant,
wherein the first sub-light emitting layer and the third sub-light emitting layer of the second blue light emitting layer comprise a third blue host and a second blue dopant, and
wherein the second sub-light emitting layer of the second blue light emitting layer comprises a fourth blue host having a lower triplet energy level than the third blue host, and the second blue dopant.

4. The light emitting display device according to claim 3, wherein a triplet energy level of the first blue dopant is higher than a triplet energy level of each of the first blue host and the second blue host.

5. The light emitting display device according to claim 3, wherein the first blue host comprises a pyrene derivative and the second blue host comprises an anthracene derivative.

6. The light emitting display device according to claim 3, wherein a highest occupied molecular orbital (HOMO) energy level of the first blue dopant is higher than a HOMO energy level of each of the first and second blue hosts, and
wherein a HOMO energy level of the second blue dopant is higher than a HOMO energy level of each of the third and fourth blue hosts.

7. The light emitting display device according to claim 3, wherein, among the first to third sub-light emitting layers of the first blue light emitting layer, the second sub-light emitting layer is thickest and the third sub-light emitting layer is thinnest, and
wherein among the first to third sub-light emitting layers of the second blue light emitting layer, the second sub-light emitting layer is thickest and the third sub-light emitting layer is thinnest.

8. The light emitting display device according to claim 7, wherein a thickness of the first sub-light emitting layer in the second blue light emitting layer is two to three times a thickness of the third sub-light emitting layer.

9. The light emitting display device according to claim 8, wherein, in the first blue light emitting layer, the thickness of the first sub-light emitting layer is greater than that of the third sub-light emitting layer and is no more than twice the thickness of the third sub-light emitting layer.

10. The light emitting display device according to claim 8, wherein the first sub-light emitting layer of the first blue light emitting layer is thinner than the first sub-light emitting layer of the second blue light emitting layer.

11. The light emitting display device according to claim 3, wherein the thickness of the first sub-light emitting layer of the second blue light emitting layer is greater than the thickness of the first sub-light emitting layer of the first blue light emitting layer and is no more than 1.5 times the thickness of the first sub-light emitting layer of the first blue light emitting layer.

12. The light emitting display device according to claim 3, wherein a concentration of the first blue dopant in the first blue light emitting layer is greater than a concentration of the second blue dopant in the second blue light emitting layer.

13. The light emitting display device according to claim 1, wherein:
the first light emitting device comprises a first red light emitting layer between the anode and the charge generation layer and a second red light emitting layer between the charge generation layer and the cathode,
the second light emitting device comprises a first green light emitting layer between the anode and the charge generation layer and a second green light emitting layer between the charge generation layer and the cathode, and
the first red light emitting layer overlaps the second red light emitting layer and is horizontally spaced from the first blue light emitting layer.

14. The light emitting display device according to claim 13, wherein the first red light emitting layer, the first green light emitting layer, and the first blue light emitting layer are in contact with an electron blocking layer commonly provided at the first to third sub-pixels,
wherein the second blue light emitting layer is in contact with a hole transport layer, and
wherein the light emitting display device further comprises a first optical compensation layer between the hole transport layer and the second red light emitting layer, and a second optical compensation layer between the hole transport layer and the second green light emitting layer.

15. The light emitting display device according to claim 1, further comprising:
a first common layer between the anode and the first blue light emitting layer; and
a second common layer between the second blue light emitting layer and the cathode,
wherein the first common layer and the second common layer extend horizontally continuously across the first light emitting device and the second light emitting device.

16. The light emitting display device according to claim 1, wherein the first blue light emitting layer contacts an electron blocking layer on a surface of the first blue light emitting layer facing the anode, and the second blue light emitting layer contacts a hole transport layer on a surface of the second blue light emitting layer facing the charge generation layer.

17. The light emitting display device according to claim 16, wherein a hole mobility of the hole transport layer is 1 to 3 orders greater than a hole mobility of the electron blocking layer.

18. The light emitting display device according to claim 1, further comprising a capping layer between the cathode and the encapsulation layer,
wherein the capping layer is thicker than the cathode.

19. The light emitting display device according to claim 1, wherein each of the first light emitting device, the second light emitting device, and the third light emitting device has an emission region defined by a bank on the planarization layer, and
wherein each of the first blue light emitting layer and the second blue light emitting layer has an edge overlapping the bank.

20. The light emitting display device according to claim 19, further comprising a touch electrode on the encapsulation layer,
wherein the touch electrode overlaps the bank.

21. The light emitting display device according to claim 20, further comprising a color filter on the touch electrode,
wherein the color filter comprising a red color filter overlapping the first light emitting device, a green color filter overlapping the second light emitting device, and a blue color filter overlapping the third light emitting device.

22. The light emitting display device according to claim 1, further comprising a plurality of inorganic insulating layers between the substrate and the transistors.

23. The light emitting display device according to claim 1, wherein the first blue light emitting layer comprises a boron-based fluorescent dopant having an emission peak at a wavelength of 420 nm to 495 nm.

24. The light emitting display device according to claim 19, wherein the bank comprises a light-shielding bank and a light-transmitting bank.

25. The light emitting display device according to claim 1, further comprising an auxiliary electrode electrically connected to the cathode through a trench provided in the bank.

26. A light emitting display device comprising:
a substrate having at least a blue sub-pixel; and
a light emitting device at the blue sub-pixel and including an anode, a cathode, and a first blue light emitting stack and a second blue light emitting stack separated by a charge generation layer between the anode and cathode;
wherein each of the first and second blue light emitting stacks comprises a first sub-light emitting layer, a second sub-light emitting layer, and a third sub-light emitting layer,
wherein for each of the first and second blue light emitting stacks, the second sub-light emitting layer comprises a host having a lower triplet energy level than a host of the first sub-light emitting layer to induce delayed fluorescence via triplet-triplet annihilation, and
wherein a thickness of the second blue light emitting stack is greater than a thickness of the first blue light emitting stack.

27. The light emitting display device of according to claim 26,
wherein the first sub-light emitting layer is disposed closer to the anode than the second and third sub-light emitting layers, and a recombination region of holes and electrons is entirely located within the first sub-light emitting layer, and
wherein the first sub-light emitting layer and the third sub-light emitting layer includes a same host material.

28. The light emitting display device according to claim 26, wherein the first blue light emitting stack is in contact with an electron blocking layer having a hole mobility at least 10 times lower than a hole mobility of a hole transport layer in contact with the second blue light emitting stack.

29. The light emitting display device according to claim 26, wherein the cathode comprises a transparent conductive material and is electrically connected to an auxiliary electrode disposed on a same layer as a connection electrode of a transistor of the light emitting device.
